(19) United States
(12) Patent Application Publication
(10) Pub. No.: US 2025/0160091 A1
(43) Pub. Date: May 15, 2025

(54) LIGHT-EMITTING DIODE, DISPLAY DEVICE INCLUDING THE LIGHT-EMITTING DIODE, AND METHOD FOR MANUFACTURING THE DISPLAY DEVICE

(71) Applicant: Samsung Display Co., Ltd., Yongin-si (KR)

(72) Inventors: Youngchul SIM, Yongin-si (KR); BYUNGJU LEE, Yongin-si (KR)

(73) Assignee: Samsung Display Co., Ltd., Yongin-si (KR)

(21) Appl. No.: 18/796,727

(22) Filed: Aug. 7, 2024

(30) Foreign Application Priority Data
Nov. 15, 2023 (KR) 10-2023-0158097

(51) Int. Cl. H01L 27/15

(52) U.S. Cl. CPC H10H 29/142

(57) ABSTRACT

A light-emitting diode includes a first electrode part, a second electrode part disposed on the first electrode part, and a semiconductor junction structure disposed between the first electrode part and the second electrode part. The semiconductor junction structure may include a first semiconductor layer, a second semiconductor layer, a third semiconductor layer, an optical layer, and an active layer. Any one of the optical layer and the active layer may be disposed between the first semiconductor layer and the second semiconductor layer, and another one of the optical layer and the active layer may be disposed between the second semiconductor layer and the third semiconductor layer. The optical layer may include a porous layer and a non-porous layer disposed on the porous layer, and in a direction perpendicular to the thickness direction, a first width of the porous layer may be greater than a second width of the non-porous layer.

### CROSS-REFERENCE TO RELATED APPLICATIONS

This application claims priority to and benefits of Korean Patent Application No. 10-2023-0158097 under 35 U.S.C. § 119, filed in the Korean Intellectual Property Office on Nov. 15, 2023, the entire contents of which are incorporated herein by reference.

### BACKGROUND

### 1. Technical Field

The disclosure relates to a light-emitting diode including a semiconductor layer, a display device including the light-emitting diode with excellent light efficiency, and a method for manufacturing the display device.

### 2. Description of the Related Art

An electronic apparatus for providing an image to a user may be a smartphone, a laptop computer, a navigation system, and a smart television and include a display device for displaying the image. For example, an augmented reality (AR) apparatus, a virtual reality (VR) apparatus, a video projection apparatus, and the like. The electronic apparatus may include a micro display device. The micro display device may include a complementary metal oxide semiconductor (CMOS) wafer and a light-emitting diode disposed on the CMOS wafer and display a high-brightness image. The micro display device may operate at low electric power. The display technology of the display devices including the light-emitting diodes has been in progress due to developments in display quality.

It is to be understood that this background of the technology section is, in part, intended to provide useful background for understanding the technology. However, this background of the technology section may also include ideas, concepts, or recognitions that were not part of what was appreciated by those skilled in the pertinent art prior to a corresponding effective filing date of the subject matter disclosed herein.

### SUMMARY

Embodiments provide a light-emitting diode with excellent light efficiency.

Embodiments also provide a display device with excellent display quality.

Embodiments also provide a method for manufacturing the display device.

However, embodiments of the disclosure are not limited to those set forth herein. The above and other embodiments will become more apparent to one of ordinary skill in the art to which the disclosure pertains by referencing the detailed description of the disclosure given below.

An embodiment of the disclosure provides a light-emitting diode including a first electrode part, a second electrode part disposed on the first electrode part, and a semiconductor junction structure disposed between the first electrode part and the second electrode part. The semiconductor junction structure includes a first semiconductor layer, a second semiconductor layer disposed on the first semiconductor layer, a third semiconductor layer disposed on the second semiconductor layer, an optical layer, and an active layer spaced apart from the optical layer in a thickness direction. Any one of the optical layer and the active layer is disposed between the first semiconductor layer and the second semiconductor layer, and another one of the optical layer and the active layer is disposed between the second semiconductor layer and the third semiconductor layer. The optical layer includes a porous layer and a non-porous layer disposed on the porous layer. In a direction perpendicular to the thickness direction, a first width of the porous layer is greater than a second width of the non-porous layer.

In an embodiment, a first refractive index of the porous layer may be smaller than a second refractive index of the non-porous layer.

In an embodiment, the porous layer, the non-porous layer, and any two of the first to third semiconductor layers may include a same semiconductor material.

In an embodiment, the optical layer may include at least one of gallium nitride (GaN), indium gallium nitride (InGaN), and aluminum gallium nitride (AlGaN).

In an embodiment, a thickness of the porous layer may satisfy Equation 1 below, and a thickness of the non-porous layer may satisfy Equation 2 below:

$${T}_{1} = {λ}_{0} / 4 {n}_{1} \qquad [ Equation 1 ]$$

$${T}_{2} = {λ}_{0} / 4 {n}_{2} \qquad [ Equation 2 ]$$

in Equation 1, n₁ is a refractive index of the porous layer, and T₁ is the thickness of the porous layer, in Equation 2, n₂ is a refractive index of the non-porous layer, and T₂ is the thickness of the non-porous layer, and in Equation 1 and Equation 2, λ₀ is a wavelength of light emitted from the active layer.

In an embodiment, a thickness of the non-porous layer may be about 2m₀+1 times a thickness of the porous layer, where m₀ is an integer of 0 or more.

In an embodiment, the optical layer may be disposed between the second semiconductor layer and the third semiconductor layer. The active layer may be disposed between the first semiconductor layer and the second semiconductor layer. Each of the second semiconductor layer and the third semiconductor layer may include an N-type semiconductor layer. The first semiconductor layer may include a P-type semiconductor layer.

In an embodiment, the optical layer may be disposed between the first semiconductor layer and the second semiconductor layer. The active layer may be disposed between the second semiconductor layer and the third semiconductor layer. Each of the first semiconductor layer and the second semiconductor layer may include an N-type semiconductor layer. The third semiconductor layer may include a P-type semiconductor layer.

In an embodiment of the disclosure, a display device includes a complementary metal oxide semiconductor (CMOS) wafer, and a plurality of light-emitting diodes disposed on the CMOS wafer. Each of the light-emitting diodes includes a first electrode part, a second electrode part disposed on the first electrode part, and a semiconductor junction structure disposed between the first electrode part and the second electrode part. The semiconductor junction structure includes a first semiconductor layer, a second semiconductor layer disposed on the first semiconductor layer, a third semiconductor layer disposed on the second semiconductor layer, an optical layer, and an active layer spaced apart from the optical layer in a thickness direction. Any one of the optical layer and the active layer is disposed between the first semiconductor layer and the second semiconductor layer, and another one of the optical layer and the active layer is disposed between the second semiconductor layer and the third semiconductor layer. The optical layer includes a porous layer and a non-porous layer disposed on the porous layer. In a direction perpendicular to the thickness direction, a first width of the porous layer is greater than a second width of the non-porous layer.

In an embodiment, a first refractive index of the porous layer may be smaller than a second refractive index of the non-porous layer.

In an embodiment, the porous layer, the non-porous layer, and any two of the first to third semiconductor layers may include a same material.

In an embodiment, the optical layer may include at least one of gallium nitride (GaN), indium nitride (InN), and indium gallium nitride (InGaN).

In an embodiment, the display device may further include a side-surface reflection layer disposed on a side surface of the first electrode part, on a side surface of the semiconductor junction structure, on a side surface of the second electrode part, and on an upper surface of the second electrode part. The side-surface reflection layer may include at least one of gold (Au), copper (Cu), silver (Ag), titanium (Ti), and aluminum (Al).

In an embodiment, the display device may further include a side-surface insulation layer disposed on the side surface of the first electrode part, on the side surface of the semiconductor junction structure, on the side surface of the second electrode part, and on the upper surface of the second electrode part. The side-surface reflection layer may be disposed on an outer side of the side-surface insulation layer.

In an embodiment, on the side surface of the semiconductor junction structure, an extending direction of the side-surface insulation layer may be inclined with respect to the thickness direction.

In an embodiment, an opening, which exposes a partial region of the upper surface of the second electrode part, may be formed through each of the side surface reflection layer and the side surface insulation layer.

In an embodiment, the plurality of light-emitting diodes may include a first light-emitting diode including a second electrode part and a second light-emitting diode including a second electrode part. The display device may further include a common electrode configured to electrically connect the second electrode part of the first light-emitting diode and the second electrode part of the second light-emitting diode. The common electrode may be in contact with the partial region through the opening.

In an embodiment, the display device may further include a plurality of lenses disposed on the plurality of light-emitting diodes and respectively corresponding to the plurality of light-emitting diodes.

In an embodiment of the disclosure, a method for manufacturing a display device includes preparing a CMOS wafer having a first silicon substrate and a conductive layer disposed on the first silicon substrate, preparing a semiconductor substrate having a preliminary semiconductor junction structure and a second silicon substrate disposed on the preliminary semiconductor junction structure, coupling the CMOS wafer and the semiconductor substrate, dry etching the preliminary semiconductor junction structure to form a semiconductor junction structure, forming a second electrode part, and forming a first electrode part. The forming of the second electrode part is performed simultaneously or after the forming of the semiconductor junction structure. The semiconductor junction structure includes a first semiconductor layer, a second semiconductor layer formed on the first semiconductor layer, a third semiconductor layer formed on the second semiconductor layer, an optical layer, and an active layer spaced apart from the optical layer in a thickness direction. Any one of the optical layer and the active layer is formed between the first semiconductor layer and the second semiconductor layer, and another one of the optical layer and the active layer is formed between the second semiconductor layer and the third semiconductor layer. The optical layer includes a porous layer and a non-porous layer disposed on the porous layer. The porous layer and the non-porous layer are formed through electro-chemical etching after the dry etching of the preliminary semiconductor junction structure.

In an embodiment, in a direction perpendicular to the thickness direction, a first width of the porous layer may be greater than a second width of the non-porous layer.

### BRIEF DESCRIPTION OF THE DRAWINGS

An additional appreciation according to the embodiments of the disclosure will become more apparent by describing in detail the elements thereof with reference to the accompanying drawings, wherein:

FIG. 1 is a schematic perspective view of a display device according to an embodiment;

FIG. 2 is a schematic cross-sectional view of a display device according to an embodiment;

FIG. 3 is a schematic plan view of a display device according to an embodiment;

FIG. 4 is a schematic plan view of a display device according to an embodiment;

FIG. 5 is a schematic enlarged plan view of region AA′ of FIG. 3;

FIG. 6 is a schematic cross-sectional view illustrating a portion corresponding to line I-I′ of FIG. 5;

FIG. 7 is a schematic enlarged cross-sectional view of region YY′ of FIG. 6;

FIG. 8 is a schematic enlarged cross-sectional view of region ZZ′ of FIG. 6;

FIG. 9 is a schematic enlarged cross-sectional view of region XX′ of FIG. 6;

FIG. 10A is a drawing schematically illustrating a light-emitting diode according to an embodiment;

FIG. 10B is a drawing schematically illustrating a light-emitting diode according to an embodiment;

FIG. 11 is a schematic cross-sectional view illustrating a portion of a light-emitting diode according to an embodiment;

FIG. 12 is a schematic cross-sectional view illustrating a portion of a light-emitting diode according to an embodiment;

FIG. 13 is a graph schematically showing the brightness according to the thickness;

FIG. 14 is a flowchart schematically illustrating a method for manufacturing a display device according to an embodiment;

FIG. 15 is a drawing schematically illustrating a manufacturing step of a display device according to an embodiment;

FIG. 16 is a drawing schematically illustrating a manufacturing step of a display device according to an embodiment;

FIG. 17 is a drawing schematically illustrating a manufacturing step of a display device according to an embodiment;

FIG. 18 is a drawing schematically illustrating a manufacturing step of a display device according to an embodiment;

FIG. 19 is a drawing schematically illustrating a manufacturing step of a display device according to an embodiment;

FIG. 20 is a drawing schematically illustrating a manufacturing step of a display device according to an embodiment;

FIG. 21 is a drawing schematically illustrating a manufacturing step of a display device according to an embodiment;

FIG. 22 is a drawing schematically illustrating a manufacturing step of a display device according to an embodiment;

FIG. 23 is a drawing schematically illustrating a manufacturing step of a display device according to an embodiment;

FIG. 24 is a drawing schematically illustrating a manufacturing step of a display device according to an embodiment;

FIG. 25 is a drawing schematically illustrating a manufacturing step of a display device according to an embodiment;

FIG. 26 is a drawing schematically illustrating a manufacturing step of a display device according to an embodiment;

FIG. 27 is a drawing schematically illustrating a manufacturing step of a display device according to an embodiment;

FIG. 28 is a drawing schematically illustrating a manufacturing step of a display device according to an embodiment; and

FIG. 29 is a drawing schematically illustrating a manufacturing step of a display device according to an embodiment.

### DETAILED DESCRIPTION OF THE EMBODIMENTS

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

When an element, such as a layer, is referred to as being “on,” “connected to,” or “coupled to” another element or layer, it may be directly disposed on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Unless otherwise specified, the illustrated embodiments are to be understood as providing features of the disclosure. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

Although the terms “first,” “second,” etc. may be used herein to describe various elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the disclosure. Further, the blocks, units, and/or modules of some embodiments may be physically combined into more complex blocks, units, and/or modules without departing from the scope of the disclosure.

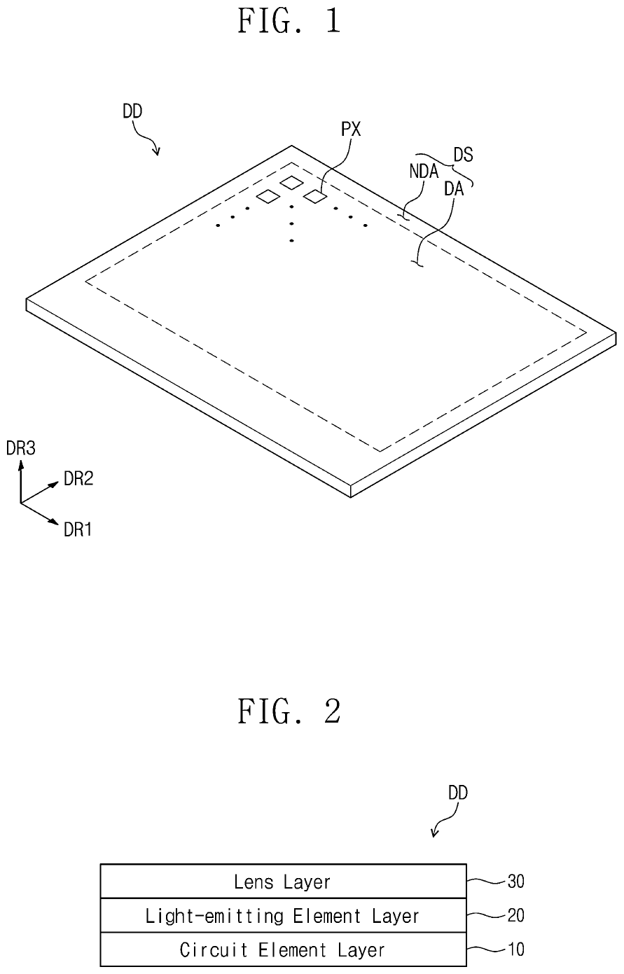

Hereinafter, embodiments of the disclosure are described with reference to the accompanying drawings. FIG. 1 is a schematic perspective view of a display device DD according to an embodiment.

Referring to FIG. 1, the display device DD may have a rectangular shape including long sides parallel to a first directional axis DR1 and short sides parallel to a second directional axis DR2 intersecting (or crossing) the first directional axis DR1. However, an embodiment of the disclosure is not limited thereto, and the display device DD may have various shapes such as a circular shape or a polygonal shape.

The display device DD according to an embodiment may be activated in response to electrical signals. For example, the display device DD may receive the electrical signals and display an image. The display device DD may be a television, a monitor, a billboard, a tablet computer, a car navigation unit, a personal computer, a laptop computer, a personal digital assistant, a game console, a smartphone, a camera, an augmented reality (AR) device, a virtual reality (VR) device, a video projection device, or the like. For example, the display device DD may be adopted to (e.g., included in) the augmented reality (AR) device. However, the disclosure is not limited thereto, and various display devices may also be adopted to (e.g., included in) the display device DD.

The display device DD may display a video (or image) through a display surface DS. The display surface DS may be parallel to a plane defined by the first directional axis DR1 and the second directional axis DR2.

The display surface DS may include a display region DA and a non-display region NDA adjacent to the display region DA. The display device DD may display an image through the display region DA. The non-display region NDA may surround the display region DA. However, the disclosure is not limited thereto, and the non-display region NDA may also be disposed adjacent only to a side of the display region DA. In other embodiments, the non-display region NDA may also be omitted.

Pixels PX may be disposed in the display region DA. The pixels PX may be disposed in the form of a matrix. The pixels PX may each include a pixel circuit and a light-emitting diode. For example, the pixels PX may generate light of a same color. In other embodiments, the pixels PX may include pixel groups that generate light of different colors.

In FIG. 1 and the following drawings, a first directional axis (or a first direction) DR1, a second directional axis (or a second direction) DR2, and a third directional axis (or a third direction) DR3 may be illustrated. In this specification, directions indicated by the first to third directional axes DR1, DR2, and DR3 are relative concepts, and may thus be changed to other directions. For example, the directions indicated by the first to third directional axes DR1, DR2, and DR3 may be described as first to third directions, and may be denoted as the same reference symbols or numbers. In this specification, the first directional axis DR1 and the second directional axis DR2 may intersect at an angle (or cross at a right angle), and the third directional axis DR3 may be the normal direction with respect to a plane defined by the first directional axis DR1 and the second directional axis DR2.

The thickness direction of the display device DD may be parallel to the third directional axis DR3 that is the normal direction with respect to the plane defined by the first directional axis DR1 and the second directional axis DR2. In this specification, a front surface (or upper surface) and a rear surface (or lower surface) of each of members constituting the display device DD may be defined on the basis of the third directional axis DR3. For example, the front surface and the rear surface of the display device DD may be normal to the third directional axis DR3. The front surface (or upper surface, upper side) may be adjacent to the display surface DS (or in a direction approaching thereto), and the rear surface (or lower surface, lower side) may be spaced apart from the display surface DS (or in a direction away therefrom). In this specification, “on a plane” means a surface parallel to the plane defined by the first directional axis DR1 and the second directional axis DR2, and “on a cross-section” means a surface parallel to the third directional axis DR3.

FIG. 2 is a schematic cross-sectional view schematically illustrating a display device DD according to an embodiment. Referring to FIG. 2, the display device DD may include a circuit element layer 10 and a light-emitting element layer 20. The display device DD may further include a lens layer 30.

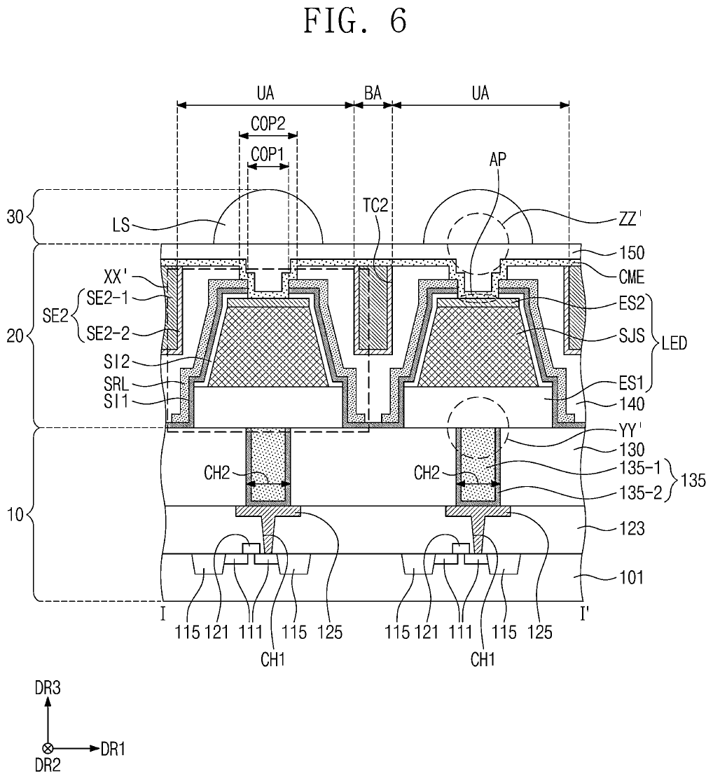

The circuit element layer 10 may include a pixel circuit. The pixel circuit may control operation of a light-emitting diode LED (e.g., refer to FIG. 6) of the light-emitting element layer 20. Detailed description of the pixel circuit is provided below. The pixel circuit may include at least one transistor. The circuit element layer 10 may include a complementary metal oxide semiconductor (CMOS) wafer. The CMOS wafer may include an nMOSFET (NMOS) and a pMOSFET (PMOS) electrically connected to each other in complementary relations. Pixel regions may be arranged regularly in the CMOS wafer, and the pixel circuit may be disposed for each pixel region.

The light-emitting element layer 20 may include a light-emitting diode LED (e.g., refer to FIG. 6) electrically connected to the pixel circuit. The light-emitting diode may be an electrically driven light-emitting diode. For example, the light-emitting diode may be a compound semiconductor and include at least one of gallium (Ga), phosphorus (P), and arsenic (As) as main semiconductor materials. In case that a forward current is applied to a P-N junction structure, electrons and holes may combine at the junction surface (e.g., an interface of the P-N junction) and generate light in a wavelength (e.g., a particular or selectable wavelength) corresponding to the band gap energy. Detailed description of the light-emitting diode LED (e.g., refer to FIG. 6) is provided below.

The lens layer 30 may be disposed on the light-emitting element layer 20 and may include a lens. The lens may correspond to the light-emitting diode. The lens may concentrate light emitted from the light-emitting diode. For example, the lens may include various types of lenses such as a multi-channel lens, a convex lens, a concave lens, a spherical lens, an aspheric lens, a single lens, a compound lens, a standard lens, a narrow-angle lens, a wide-angle lens, a fixed-focus lens, a variable-focus lens, or the like. However, the disclosure is not limited thereto.

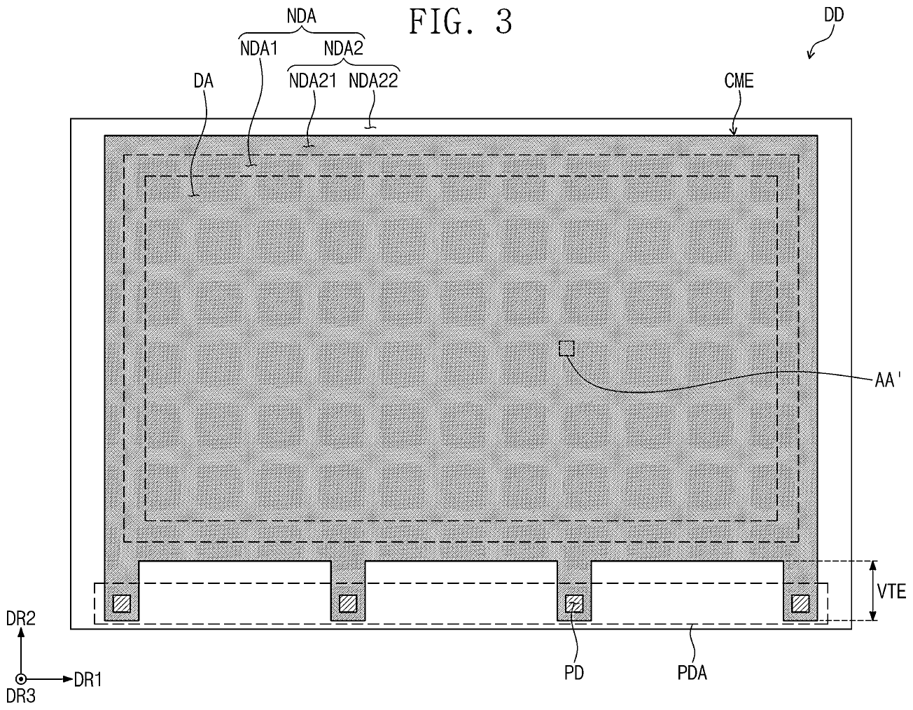

FIG. 3 is a schematic plan view illustrating a common electrode CME disposed in a display region DA and a non-display region NDA of a display device DD. The display region DA and the non-display region NDA of the display device DD may also be equally applied to the circuit element layer 10, which is the CMOS wafer, described with reference to FIG. 2. Hereinafter, the circuit element layer 10 (e.g., refer to FIG. 2) may be described as the CMOS wafer 10 (e.g., refer to FIG. 2) and denoted as a same reference numeral.

The common electrode CME may cover at least the display region DA. The common electrode CME may transfer a power voltage, which is applied from the outside, to an entire area of the display region DA. Hereinafter, the display region DA may be described as a first region DA and denoted as a same reference symbol.

The non-display region NDA may be divided into multiple regions. The non-display region NDA may include a second region NDA1 and a third region NDA2. The second region NDA1 may be disposed in the outside of the first region DA, and dummy light-emitting diodes (not shown) may be disposed in the second region NDA1. For example, the second region NDA1 may be adjacent to (e.g., surround) the first region DA. However, an embodiment of the disclosure is not limited thereto. The dummy light-emitting diodes and the light-emitting diode in the first region DA may have a same stacked structure. However, the dummy light-emitting diodes may not be electrically connected to the common electrode CME and may not operate (or emit light).

In case that the light-emitting diodes (e.g., the light-emitting diode in the first region DA and the dummy light-emitting diodes) are formed through a same process in a region (e.g., a particular or selectable region), the outside region (e.g., a region in which the dummy light-emitting diodes are formed) and the inside region (e.g., the first region DA) may be formed with different process conditions. For example, the thickness of a deposited component may be small, or the etch rate may be different. Accordingly, a poor light-emitting diode may be formed in the outside region. Thus, the light-emitting diode (e.g., the poor light-emitting diode) formed on the outside may be used as a dummy light-emitting diode and may not be a valid light-emitting diode (e.g., the light-emitting diode in the first region DA). However, the disclosure is not limited thereto, and the dummy light-emitting diode and the second region NDA1 may be omitted.

The third region NDA2 may include an inside region NDA21 (hereinafter, 3-1-th region) and an outside region NDA22 (hereinafter, 3-2-th region) distinguished according to whether the common electrode CME is disposed or not. For example, the common electrode CME may be disposed in the 3-1-th region NDA21 and may not be disposed in the 3-2-th region NDA22. The 3-1-th region NDA21 may be disposed more adjacent to the first region DA than the 3-2-th region NDA22. The 3-2-th region NDA22 may be spaced apart from the first region DA, and the 3-1-th region NDA21 may be disposed between the first region DA and the 3-2-th region NDA22.

The common electrode CME may be disposed in the 3-1-th region NDA21, and the light-emitting diode or the dummy light-emitting diode may not be disposed in the 3-1-th region NDA21. For example, the 3-1-th region NDA21 may be adjacent to (e.g., surround) the second region NDA1. However, an embodiment of the disclosure is not limited thereto. The scope of the 3-1-th region NDA21 may be determined by an edge of the common electrode CME.

The common electrode CME may not be disposed in the 3-2-th region NDA22. For example, the 3-2-th region NDA22 may be adjacent to (e.g., surround) the 3-1-th region NDA21. However, an embodiment of the disclosure is not limited thereto. Driving circuits may be disposed in the 3-2-th region NDA22 of the CMOS wafer 10 (e.g., refer to FIG. 2). For example, a scan driver may be disposed in each of the left-side region and the right-side region of the 3-2-th region NDA22 in a first direction (or a first directional axis) DR1, and the first region DA may be disposed between the left-side region and the right-side region of the 3-2-th region NDA22 in the first direction DR1. A data driver may be disposed in a partial region of the 3-2-th region NDA22 disposed on a lower side of the first region DA in a second direction (or a second directional axis) DR2. An analog circuit, such as a power circuit, may also be disposed in a partial region of the 3-2-th region NDA22. The scan driver, the data driver, and the analog circuit may be embedded in the CMOS wafer. For example, the scan driver, the data driver, and the analog circuit may include transistors. The pixel circuits and the transistors of the scan driver, the data driver, and the analog circuit may be formed in a same method.

A pad region PDA, in which pad electrodes PD are disposed, may be disposed on a side (e.g., a lower side) of the 3-2-th region NDA22. The pad region PDA may correspond to a partial region of the 3-2-th region NDA22. A circuit board may be electrically connected to the pad region PDA. FIG. 3 illustrates only four pad electrodes PD which receive power voltages applied to the common electrode CME. However, the disclosure is not limited thereto, and more pad electrodes may be disposed in the pad region PDA. The pad electrodes that are not illustrated may receive a data image signal or control signals from the outside, and provide the received signals to the data driver.

A voltage transmission electrode VTE may be disposed in the 3-2-th region NDA22. Referring to FIG. 3, four voltage transmission electrodes VTE may correspond to (e.g., be electrically connected to) the four pad electrodes PD. The voltage transmission electrode VTE may extend from the common electrode CME toward the pad region PDA. The voltage transmission electrode VTE and the common electrode CME may be formed through a same process and have a same stacked structure and an integrated form. The voltage transmission electrode VTE and the common electrode CME may be different portions in an electrode formed through a same process.

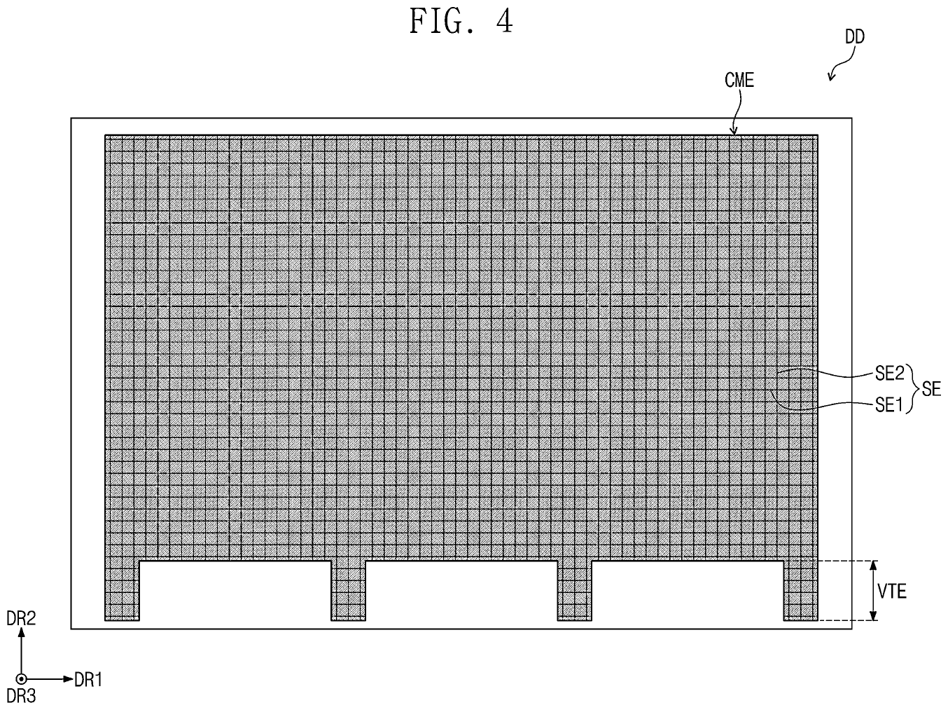

FIG. 4 is a schematic plan view illustrating the arrangement relationship of a common electrode CME, a voltage transmission electrode VTE, and an auxiliary electrode SE. The auxiliary electrode SE may overlap each of the common electrode CME and the voltage transmission electrode VTE. In a thickness direction (e.g., a third directional axis or a third direction) DR3, the auxiliary electrode SE may be disposed under the common electrode CME and the voltage transmission electrode VTE. In the thickness direction DR3, the auxiliary electrode SE may be disposed inside a trench disposed under the common electrode CME and the voltage transmission electrode VTE. Detailed description of a cross-section of the arrangement relationship of the auxiliary electrode SE, the common electrode CME, and the voltage transmission electrode VTE is provided below.

In this specification, a component overlapping another component means overlapping. A component overlapping another component is not limited to the components having a same area and a same shape, and also includes components having different areas and/or shapes from each other.

The auxiliary electrode SE may include first auxiliary electrodes SE1 extending in a first direction (or a first directional axis) DR1, and second auxiliary electrodes SE2 extending in a second direction (or a second directional axis) DR2. The first auxiliary electrodes SE1 may be arranged in the second direction DR2, and the second auxiliary electrodes SE2 may be arranged in the first direction DR1.

A portion of the auxiliary electrode SE may overlap the common electrode CME and may be electrically connected to (e.g., be entirely connected to) the common electrode CME. Thus, voltage drop may be reduced in the common electrode CME. Another portion of the auxiliary electrode SE may overlap the voltage transmission electrode VTE, and another portion may be electrically connected to (e.g., be entirely connected to) the voltage transmission electrode VTE. Thus, resistance of a voltage transmission path between the pad electrode PD (e.g., refer to FIG. 3) and the common electrode CME may be decreased. The auxiliary electrode SE (e.g., the auxiliary electrodes SE in the display region DA and the non-display region NDA) may be formed through a same process regardless of the regions, and may have an integrated form.

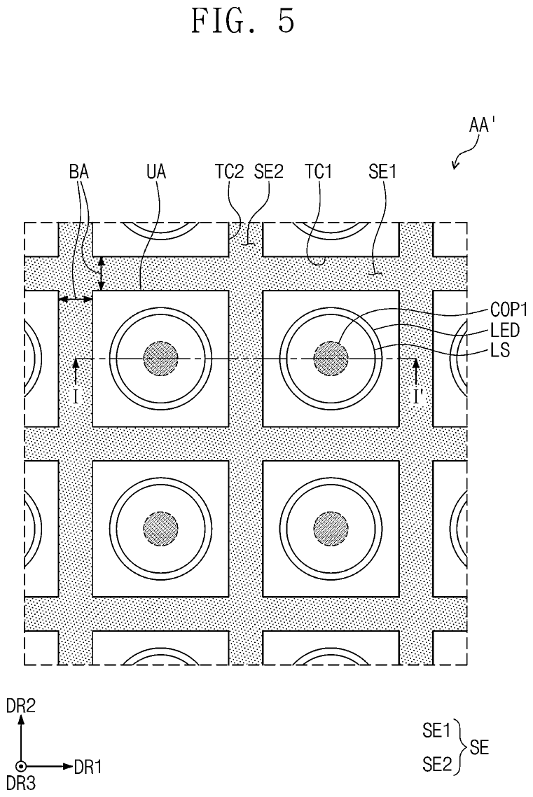

FIG. 5 is a schematic enlarged plan view illustrating region AA′ of a first region DA in FIG. 3. FIG. 6 is a schematic cross-sectional view illustrating a portion taken along line I-I′ of FIG. 5.

Referring to FIG. 5, an auxiliary electrode SE may include first auxiliary electrodes SE1 and second auxiliary electrodes SE2. The first auxiliary electrodes SE1 and the second auxiliary electrodes SE2 may intersect (or cross) each other. The first auxiliary electrodes SE1 may be respectively disposed in first trenches TC1, and the second auxiliary electrodes SE2 may be respectively disposed in second trenches TC2.

The first region DA (e.g., refer to FIG. 3) may include unit regions UA, and a boundary region BA between the unit regions UA. The regions UA may each be an inside region (or a boundary region) defined by adjacent ones of the first trenches TC1 and adjacent ones of the second trenches TC2. The first trenches TC1 and the second trenches TC2 are positioned in the boundary region BA.

Referring to FIG. 5, light-emitting diodes LED and lenses LS may be disposed in the unit regions UA. For example, each of the light-emitting diodes LED and each of the lenses LS may be disposed in each of the unit regions UA. First openings COP1 may be defined in the unit regions UA. For example, each of the first openings COP1 may be disposed in each of the unit regions UA.

Through the first openings COP1, a common electrode CME in FIG. 6 and light-emitting diodes LED in FIG. 6 may be electrically connected to each other. The first openings COP1 may each be defined inside a corresponding lens LS of the lenses LS. The lenses LS may each be disposed inside a corresponding light-emitting diode LED of the light-emitting diodes LED.

FIG. 6 may be a cross-sectional view schematically illustrating the configuration of the display device DD in FIG. 2. The display device DD (e.g., refer to FIG. 2) may include a CMOS wafer 10, a light-emitting element layer 20, and a lens layer 30 stacked one another in sequence.

The CMOS wafer 10 may include a silicon substrate 101. Source/drain regions 111 may be defined in the silicon substrate 101. The source/drain regions 111 may each be a region doped with a dopant. The source/drain regions 111 may be a source of a transistor or a drain of the transistor according to flow of a signal. A pair of source/drain regions 111 and a gate 121 may define a transistor. Detailed description of the pair of the source/drain regions 111 is provided below.

Shallow trench isolation regions (STI) 115 may further be defined in the silicon substrate 101. The STI regions 115 may isolate the transistor and prevent leakage current. The arrangement of the STI regions 115 may vary according to the design of a pixel circuit.

Gates 121 may be disposed on the silicon substrate 101. The gates 121 may include metal. The gates 121 may each correspond to a pair of source/drain regions 111. A first insulation layer 123 may be disposed on the silicon substrate 101. The first insulation layer 123 may include a single layer or multiple layers. For example, the first insulation layer 123 may include at least one of silicon oxide, silicon nitride, silicon oxynitride, and aluminum oxide. However, the disclosure is not limited thereto.

The CMOS wafer 10 may include a first contact electrode 125. The first contact electrode 125 may be electrically connected to the source/drain region 111 through a first contact hole CH1 defined in the first insulation layer 123. Upper surfaces of the first contact electrode 125 and the first insulation layer 123 may define a same flat surface (or planarized surface). The first contact electrode 125 may be formed through a damascene method. The first contact electrode 125 may include metal such as copper, tungsten, an alloy thereof, or the like. However, the disclosure is not limited thereto.

A second insulation layer 130 may be disposed on the first insulation layer 123. A second contact hole CH2 that exposes the first contact electrode 125 may be defined in the second insulation layer 130. The second insulation layer 130 may include a single layer or multiple layers. For example, the second insulation layer 130 may include at least one of silicon oxide, silicon nitride, silicon oxynitride, and aluminum oxide. However, the disclosure is not limited thereto.

A second contact electrode 135 may be disposed in the second contact hole CH2. Upper surfaces of the second contact electrode 135 and the second insulation layer 130 may define a same flat surface (or planarized surface). The second contact electrode 135 may include a metal structure 135-1 and a barrier layer 135-2. The metal structure 135-1 may be disposed inside the second contact hole CH2. The barrier layer 135-2 may be disposed between a side surface of the metal structure 135-1 and an inner side surface of the second contact hole CH2, and between a lower surface of the metal structure 135-1 and an upper surface of the first contact electrode 125. For example, the barrier layer 135-2 may extend from the upper surface of the first contact electrode 125 to the side surface of the metal structure 135-1. The upper surface of the first contact electrode 125 may be exposed through the second contact hole CH2.

The metal structure 135-1 may include metal such as copper, tungsten, an alloy thereof, or the like. However, the disclosure is not limited thereto. The barrier layer 135-2 may have electrical conductivity. The barrier layer 135-2 may increase bonding forces of the second contact electrode 135 for the second insulation layer 130 and for the first contact electrode 125. For example, the barrier layer 135-2 may increase the bonding force between the second contact electrode 135 and the second insulation layer 130 and the bonding force between the second contact electrode 135 and the first contact electrode 125. Thus, the barrier layer 135-2 may prevent metal atoms of the metal structure 135-1 from diffusing to the second insulation layer 130.

The barrier layer 135-2 may include a barrier metal layer and a barrier-metal nitride layer. The barrier-metal nitride layer may be disposed more adjacent to the second insulation layer 130 than the barrier metal layer. The barrier metal layer may increase the bonding forces, and the barrier-metal nitride layer may prevent the metal atoms included in the metal structure 135-1 from diffusing (e.g., from diffusing toward the second insulation layer 130). The barrier metal may include titanium, tantalum, or an alloy thereof. The barrier layer 135-2 may include a titanium nitride layer and a titanium layer, or may include a tantalum nitride layer and a tantalum layer. However, the disclosure is not limited thereto.

The second contact electrode 135 may include a tungsten structure, a titanium layer adjacent to (e.g., surrounding) a side surface and a lower surface of the tungsten structure, and a titanium nitride layer adjacent to (e.g., surrounding) the titanium layer. The second contact electrode 135 may include a copper structure, a tantalum layer adjacent to (e.g., surrounding) a side surface and a lower surface of the copper structure, and a tantalum nitride layer adjacent to (e.g., surrounding) the tantalum layer.

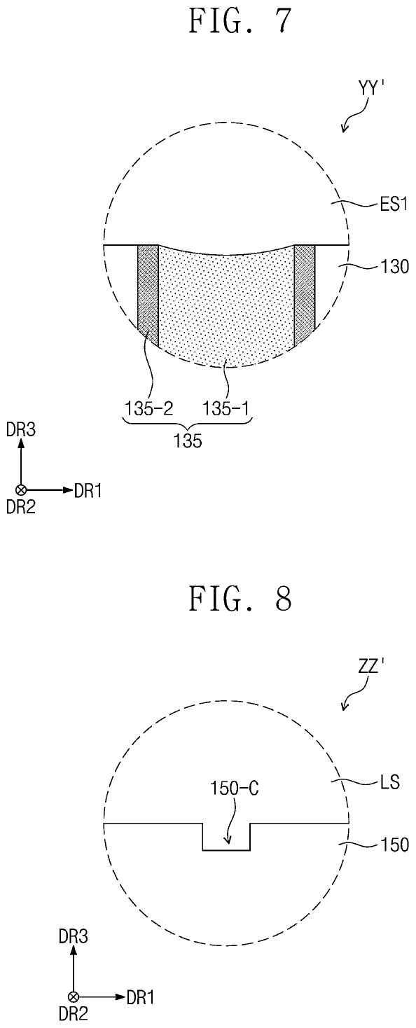

FIG. 7 is a schematic enlarged cross-sectional view illustrating region YY′ which is a contact region of the second contact electrode 135 and a first electrode part ES1. As illustrated in FIG. 7, an upper surface of the second contact electrode 135 may be concave. The concave upper surface of the second contact electrode 135 may be in contact with the first electrode part ES1. Detailed description of the first electrode part ES1 is provided below. The second contact electrode 135 may be formed through a damascene method. In a chemical mechanical polishing (CMP) process of the damascene method, the polishing degree of the second insulation layer 130 may be greater than the polishing degree of the second contact electrode 135. Thus, a dishing phenomenon may occur in the second contact electrode 135.

Referring to FIG. 6 again, the light-emitting diode LED may be disposed on the second insulation layer 130. The light-emitting diodes LED, illustrated in FIG. 6, may generate light in a same wavelength range. In other embodiments, the light-emitting diodes LED may generate light in different wavelength ranges from each other. For example, one of the four light-emitting diodes LED illustrated in FIG. 5 may generate red light, another of the light-emitting diodes LED may generate green light, and another of the light-emitting diodes LED may generate blue light. Remaining one of the light-emitting elements LED may generate one of the red light, the green light, the blue light, and white light. For example, the four light-emitting diodes LED may generate the red light, the green light, the blue light, and the white light (or other light), respectively.

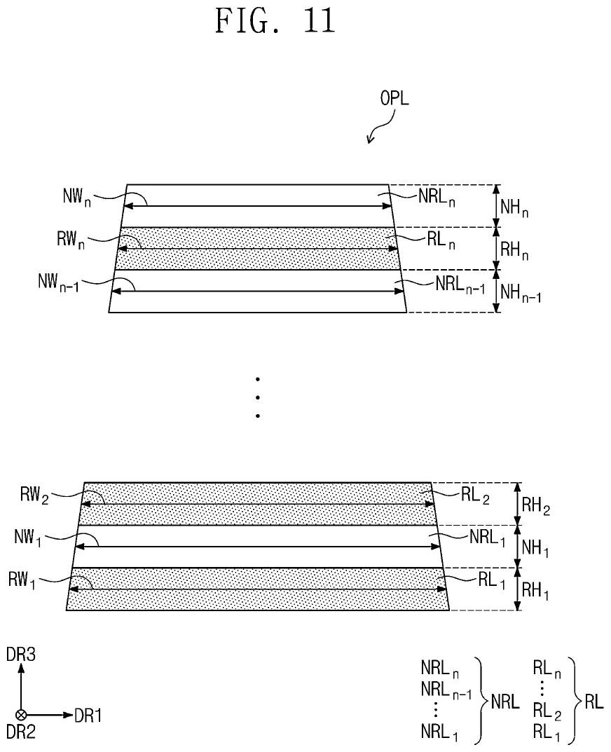

Referring to FIG. 6, the light-emitting diode LED may include a first electrode part ES1, a second electrode part ES2 disposed on the first electrode part ES1, and a semiconductor junction structure SJS disposed between the first electrode part ES1 and the second electrode part ES2. The light-emitting diode LED according to an embodiment may include a porous layer RL (e.g., refer to FIG. 11) and a non-porous layer NRL (e.g., refer to FIG. 11). Detailed description of the porous layer RL and the non-porous layer NRL is provided below. Thus, the light-emitting diode LED may have excellent light efficiency without an increase in thickness. For example, luminance of the light-emitting diode LED may have increased, and the thickness of the display device DD (e.g., refer to FIG. 1) may be decreased. The display device DD including the light-emitting diode LED, according to an embodiment, may provide excellent display efficiency and display quality.

The first electrode part ES1 may be in contact with the second contact electrode 135. In a first direction (or a first directional axis) DR1, the first electrode part ES1 may have a greater width (or diameter) than that of each of the semiconductor junction structure SJS and the second electrode part ES2. The semiconductor junction structure SJS and the second electrode part ES2 may be disposed inside the first electrode part ES1. In other embodiments, the first electrode part ES1, the semiconductor junction structure SJS, and the second electrode part ES2 may have a same width (or diameter).

Hereinafter, the first electrode part ES1 may be an anode, and the second electrode part ES2 may be a cathode. However, an embodiment of the disclosure is not limited thereto. In other embodiments, the first electrode part ES1 may be a cathode, and the second electrode part ES2 may be an anode.

The light-emitting element layer 20 may include a first side-surface insulation layer SI1 disposed adjacent to a side surface of the light-emitting diode LED. The first side-surface insulation layer SI1 may be adjacent to (e.g., surround) the light-emitting diode LED except the first opening COP1 and a lower surface of the first electrode part ES1. For example, the first opening COP1 may pass through the first side-surface insulation layer SI1.

The first side-surface insulation layer SI1 may prevent the light-emitting diode LED and a side-surface reflection layer SRL from coming into contact with each other. For example, the light-emitting diode LED may be electrically insulated from the side-surface reflection layer SRL by the first side-surface insulation layer SI1. For example, the first side-surface insulation layer SI1 may include at least one of silicon oxide, silicon nitride, silicon oxynitride, aluminum oxide, zirconium oxide, hafnium oxide, and titanium oxide. However, the disclosure is not limited thereto.

The side-surface reflection layer SRL may be disposed on an outer side of the first side-surface insulation layer SI1. The side-surface reflection layer SRL may reflect light generated from the light-emitting diode LED and increase light efficiency. Thus, the light generated from the light-emitting diode LED may be emitted through the first opening COP1. The side-surface reflection layer SRL may include at least one of gold (Au), copper (Cu), silver (Ag), titanium (Ti), and aluminum (Al). However, the disclosure is not limited thereto.

For example, multiple side-surface reflection layers SRL may be disposed on the outer side of the first side-surface insulation layer SI1. The side-surface reflection layers SRL may be disposed apart from each other respectively for the light-emitting diodes LED. The side-surface reflection layers SRL may be separated and spaced apart from each other in a boundary region BA. For example, the boundary region BA may be disposed between adjacent ones of the side-surface reflection layers SRL. However, an embodiment of the disclosure is not limited thereto, and the side-surface reflection layer SRL may have an integrated form. In case that the side-surface reflection layer SRL has an integrated form, the side-surface reflection layer SRL may have the integrated form in the first region DA in FIG. 3.

The light-emitting element layer 20 may further include a second side-surface insulation layer SI2 disposed on an inner side of the first side-surface insulation layer SI1. The second side-surface insulation layer SI2 may protect a partial region of the side surface of the light-emitting diode LED during a manufacturing process for a light-emitting diode LED. The second side-surface insulation layer SI2 may include a single layer or multiple layers. The second side-surface insulation layer SI2 may include at least one of silicon oxide, silicon nitride, silicon oxynitride, aluminum oxide, zirconium oxide, hafnium oxide, and titanium oxide. However, the disclosure is not limited thereto.

The first opening COP1 may correspond to a light-emitting region of the light-emitting diode LED. The first opening COP1 may correspond to a path electrically connecting the second electrode part ES2 to the common electrode CME. For example, the second electrode part ES2 may be electrically connected to the common electrode CME through the first opening COP1.

A planarization layer 140 may be disposed on the second insulation layer 130. The planarization layer 140 may overlap unit regions UA and a boundary region BA and may be disposed on multiple light-emitting diodes LED. The planarization layer 140 may fill a region in which the light-emitting diodes LED are not disposed. The planarization layer 140 may include an organic material.

The planarization layer 140 may be in contact with the side-surface reflection layer SRL. A second opening COP2 overlapping the first opening COP1 may be disposed in the planarization layer 140. For example, the second opening COP2 may pass through the planarization layer 140. The second opening COP2 may be aligned with the first opening COP1. The first opening COP1 and the second opening COP2 may be formed through different processes from each other. The second opening COP2 may be formed in the area greater than that of the first opening COP1.

However, the disclosure is not limited thereto. The planarization layer 140 may not be disposed on an upper side of the second electrode part ES2. Upper surfaces of the planarization layer 140 and the side-surface reflection layer SRL may define a same flat surface. The second opening COP2 may also be omitted.

The trenches TC1 and TC2 (e.g., refer to FIG. 5) may be defined on the planarization layer 140. In FIG. 6, the second trenches TC2 are disposed in the boundary region BA between adjacent ones of unit regions UA. Second auxiliary electrodes SE2 may be disposed on the second trenches TC2. The first auxiliary electrodes SE1 (e.g., refer to FIG. 5) and the second auxiliary electrodes SE2 may be formed through a same process and may have a same structure.

The second auxiliary electrode SE2 may be formed through a damascene method. For example, the second contact electrode 135 may be formed through a damascene method. An upper surface of the second auxiliary electrode SE2 may be concave. The second auxiliary electrode SE2 may include a metal structure SE2-1 disposed inside the second trench TC2 and a barrier layer SE2-2 disposed between the metal structure SE2-1 and the second trench TC2. The metal structure SE2-1 may include metal such as copper, tungsten, or an alloy thereof. The metal structure SE2-1 and the barrier layer SE2-2 may have electrical conductivity. The barrier layer SE2-2 may increase bonding force of the second auxiliary electrode SE2 for the planarization layer 140, and prevent metal atoms of the metal structure SE2-1 from diffusing to the planarization layer 140.

The barrier layer SE2-2 may include a barrier metal layer and a barrier-metal nitride layer. The barrier-metal nitride layer may be disposed more adjacent to the planarization layer 140 than the barrier metal layer. For example, the barrier-metal nitride layer may be in contact with the planarization layer 140, and the barrier metal layer may be in contact with the metal structure SE2-1. The barrier metal layer may include titanium, tantalum, or an alloy thereof. The barrier-metal nitride layer may include a titanium nitride layer or a tantalum nitride layer.

A common electrode CME may be disposed on the planarization layer 140. The common electrode CME may overlap the unit regions UA and the boundary region BA. The common electrode CME may include a transparent conductive material emitting light generated from the light-emitting diode LED. The common electrode CME may include a transparent conductive oxide including at least one of indium tin oxide (ITO), indium zinc oxide (IZO), zinc oxide (ZnO), zinc tin oxide (ZTO), and indium gallium zinc oxide (IGZO). However, the disclosure is not limited thereto.

The common electrode CME may be electrically connected to the second electrode parts ES2 of the light-emitting diodes LED through the first openings COP1 and the second openings COP2. The common electrode CME may be in contact with a partial region AP of each of the second electrode parts ES2 through the first openings COP1 and the second openings COP2. The partial region AP of the second electrode part ES2 may be exposed by the first opening COP1 and the second opening COP2.

A power voltage may be applied through the common electrode CME and transferred to the light-emitting diode LED. FIG. 6 schematically illustrates the common electrode CME electrically connected to two light-emitting diodes LED. Any one of the two light-emitting diodes LED may be defined as a first light-emitting diode LED, and another of the two light-emitting diodes LED may be defined as a second light-emitting diode LED.

The common electrode CME may be in contact with upper surfaces of the second auxiliary electrodes SE2. Since the upper surface of each of the second auxiliary electrodes SE2 is in contact with the common electrode CME along a length direction (e.g., the second direction DR2) of the second trench TC2, the common electrode CME and the second auxiliary electrodes SE2 may secure a sufficient contact area. For example, the contact area between the common electrode CME and the second auxiliary electrodes SE2 may be increased by the second trench TC2.

A third insulation layer 150 may be disposed on the common electrode CME. The third insulation layer 150 may protect the common electrode CME. The third insulation layer 150 may overlap the display region DA and the non-display region NDA (e.g., refer to FIG. 3), and protect the voltage transmission electrodes VTE (e.g., refer to FIGS. 3 and 4). The third insulation layer 150 may include an organic material or an inorganic material.

Lenses LS may be disposed on the third insulation layer 150. FIG. 6 illustrates two lenses LS respectively corresponding to the first and second light-emitting diodes LED. The lenses LS may concentrate light emitted from the light-emitting diodes LED. The lenses LS may include an organic material and may have a domelike shape (e.g., a semi-spherical shape). For example, in the first direction (or the first directional axis) DR1, the diameter of each of the lenses LS may be less than or equal to about 1 μm.

FIG. 8 is a schematic enlarged cross-sectional view illustrating region ZZ′ which is a contact region of the third insulation layer 150 and the lens LS in FIG. 6. In FIGS. 6 and 8, the third insulation layer 150 may include a concave region 150-C. A step may be formed in a region corresponding to the first opening COP1 in FIG. 6, and the step may be transferred to the common electrode CME and/or the third insulation layer 150. The step may also be omitted according to the material and/or thickness of the third insulation layer 150.

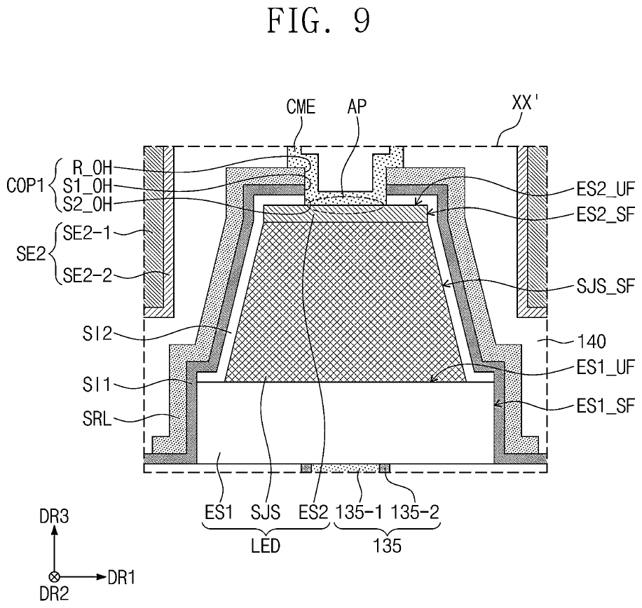

FIG. 9 is a schematic enlarged cross-sectional view illustrating region XX′ of FIG. 6. Referring to FIG. 9, a side surface SJS_SF of the semiconductor junction structure SJS may be inclined. For example, the side surface SJS_SF of the semiconductor junction structure SJS may be inclined at an angle with respect to an upper surface of the silicon substrate 101 (e.g., refer to FIG. 6). The side surface SJS_SF of the semiconductor junction structure SJS may not be parallel to a thickness direction (e.g., the third direction or the third directional axis) DR3. The side surface SJS_SF of the semiconductor junction structure SJS may not be perpendicular to an upper surface ES1_UF of the first electrode part ES1. In a method for manufacturing a display device according to an embodiment, the semiconductor junction structure SJS may be formed through a dry-etching process, and may include the side surface SJS_SF which is not parallel to the thickness direction DR3. Detailed description of the method for manufacturing a display device according to an embodiment is provided below.

A side surface ES2_SF of the second electrode part ES2 may be substantially parallel to the thickness direction DR3. To be substantially parallel includes not only being parallel without an error, but also having differences within a process error range.

A second side-surface insulation layer SI2 may be in contact with the side surface SJS_SF of the semiconductor junction structure SJS and the side surface ES2_SF of the second electrode part ES2. In the second side-surface insulation layer SI2, the extending direction of a portion in contact with the side surface SJS_SF of the semiconductor junction structure SJS may be inclined with respect to the thickness direction DR3. In the second side-surface insulation layer SI2, the extending direction of a portion in contact with the side surface ES2_SF of the second electrode part ES2 may be substantially parallel to the thickness direction DR3. The second side-surface insulation layer SI2 may further be disposed in a partial region of an upper surface ES2_UF of the second electrode part ES2. The second side-surface insulation layer SI2 may further be disposed in a region of the upper surface ES1_UF of the first electrode part ES1 in which the semiconductor junction structure SJS is not disposed. For example, the second side-surface insulation layer SI2 may be formed along a profile formed by at least part of the first electrode part ES1, the semiconductor junction SJS, and the second electrode part ES2. In the second side-surface insulation layer SI2, a first sub opening S2_OH that exposes a partial region AP of the upper surface ES2_UF of the second electrode part ES2 may be defined.

The first side-surface insulation layer SI1 may be spaced apart from the side surface SJS_SF of the semiconductor junction structure SJS, the side surface ES2_SF of the second electrode part ES2, and the upper surface ES2_UF of the second electrode part ES2. The second side-surface insulation layer SI2 may be disposed between the first side-surface insulation layer SI1 and the side surface SJS_SF of the semiconductor junction structure SJS, the side surface ES2_SF of the second electrode part ES2, and the upper surface ES2_UF of the second electrode part ES2. The first side-surface insulation layer SI1 may be disposed on the side surface ES1_SF of the first electrode part ES1, the side surface SJS_SF of the semiconductor junction structure SJS, the side surface ES2_SF of the second electrode part ES2, and the upper surface ES2_UF of the second electrode part ES2. For example, the first side-surface insulation layer SI1 may extend from the side surface ES1_SF of the first electrode part ES1 toward the upper surface ES2_UF of the second electrode part ES2 through the side surface SJS_SF of the semiconductor junction structure and the side surface ES2_SF of the second electrode part ES2, in sequence. The first side-surface insulation layer SI1 may further be disposed on the upper surface ES1_UF of the first electrode part ES1. On the side surface SJS_SF of the semiconductor junction structure SJS, the extending direction of the first side-surface insulation layer SI1 may be inclined with respect to the thickness direction DR3. For example, in the first side-surface insulation layer SI1, the extending direction of a portion disposed on the side surface SJS_SF of the semiconductor junction structure SJS may be inclined with respect to the thickness direction DR3. For example, the first side-surface insulation layer SI1 may be disposed along a profile formed by the second side-surface insulation layer SI2 and the first electrode part ES1. In the first side-surface insulation layer SI1, a second sub opening S1_OH that exposes the partial region AP of the upper surface ES2_UF of the second electrode part ES2 may be defined.

The side-surface reflection layer SRL may be spaced apart from the first electrode part ES1 and the semiconductor junction structure SJS. The first side-surface insulation layer SI1 may be disposed between the side-surface reflection layer SRL and the first electrode part ES1. The side-surface reflection layer SRL may be disposed on the side surface ES1_SF of the first electrode part ES1, the side surface SJS_SF of the semiconductor junction structure SJS, the side surface ES2_SF of the second electrode part ES2, and the upper surface ES2_UF of the second electrode part ES2. On the side surface SJS_SF of the semiconductor junction structure SJS. For example, the side-surface reflection layer SRL may extend from the side surface ES1_SF of the first electrode part ES1 toward the upper surface ES2_UF of the second electrode part ES2 through the side surface SJS_SF of the semiconductor junction structure SJS and the side surface ES2_SF of the second electrode part ES2, in sequence. The extending direction of the side-surface reflection layer SRL may be inclined with respect to the thickness direction DR3. For example, in the side-surface reflection layer SRL, the extending direction of a portion disposed on the side surface SJS_SF of the semiconductor junction structure SJS may be inclined with respect to the thickness direction DR3. For example, the side surface reflection layer SRL may be disposed along a profile of the first side-surface insulation layer SI1. In the side-surface reflection layer SRL, a third sub opening R_OH that exposes the partial region AP of the upper surface ES2_UF of the second electrode part ES2 may be defined.

The first sub opening S2_OH of the second side-surface insulation layer SI2, the second sub opening S1_OH of the first side-surface insulation layer SI1, and the third sub opening R_OH of the side-surface reflection layer SRL may form a first opening COP1. An inner side surface of the second side-surface insulation layer SI2 defining the first sub opening S2_OH, an inner side surface of the first side-surface insulation layer SI1 defining the second sub opening S1_OH, and an inner side surface of the side-surface reflection layer SRL defining the third sub opening R_OH may be parallel to each other. The common electrode CME may be in contact with the partial region AP of the upper surface ES2_UF of the second electrode part ES2 through the first opening COP1.

The planarization layer 140 may be disposed on the side surface ES1_SF of the first electrode part ES1 and on the side surface SJS_SF of the semiconductor junction structure SJS. For example, the planarization layer 140 may be disposed on the side-surface reflection layer SRL along a profile formed by the side surface ES1_SF of the first electrode part ES1 and the side surface SJS_SF of the semiconductor junction structure SJS. A portion of the planarization layer 140 may correspond to the side surface ES2_SF of the second electrode part ES2, and another portion may be disposed on the second electrode part ES2 and overlap the side-surface reflection layer SRL.

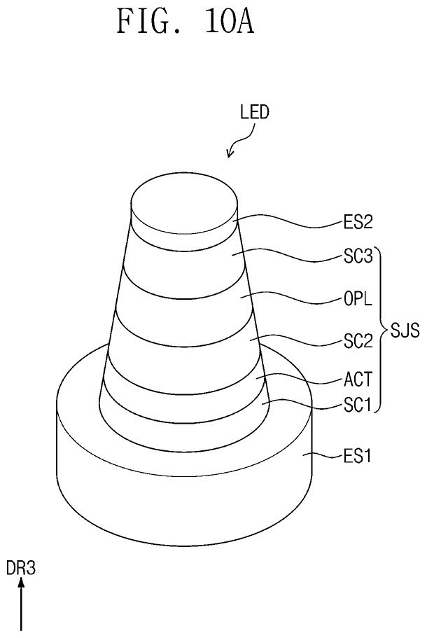

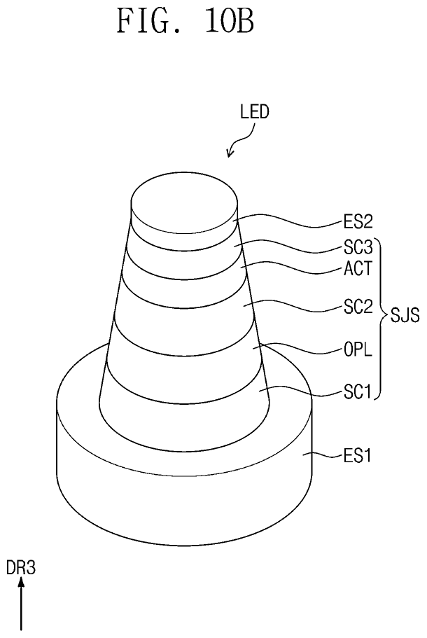

FIGS. 10A and 10B are drawings schematically illustrating the light-emitting diode LED in FIG. 6. The light-emitting diode LED may include a first electrode part ES1, a semiconductor junction structure SJS, and a second electrode part ES2.

Referring to FIGS. 10A and 10B, the light-emitting diode LED may have a column shape. The light-emitting diode LED may have a size that ranges from a nanometer scale to a micrometer scale. The light-emitting diode LED may have a diameter (or width) and/or length of a nanometer scale to a micrometer scale. The diameter (or width) may mean a diameter (or width) in a direction perpendicular to a thickness direction (e.g., the third direction or the third directional axis) DR3, and the length may mean a length in the thickness direction DR3. However, the size of the light-emitting diode LED is not limited thereto, and the size of the light-emitting diode LED may vary according to the design condition of different apparatuses using light-emitting devices, which use the light-emitting diodes LED, as light sources.

For example, in the light-emitting diode LED, the semiconductor junction structure SJS may have a truncated cone shape. In an embodiment, the semiconductor junction structure SJS may include a first semiconductor layer SC1, a second semiconductor layer SC2 disposed on the first semiconductor layer SC1, a third semiconductor layer SC3 disposed on the second semiconductor layer SC2, an optical layer OPL, and an active layer ACT. In a method for manufacturing a display device according to an embodiment, the semiconductor junction structure SJS of the light-emitting diode LED may be formed through a dry-etching process, and may be manufactured in the truncated cone shape. Detailed description of the method for manufacturing the display device according to the embodiment is provided below. In the semiconductor junction structure SJS having the truncated cone shape, the diameters of the first to third semiconductor layers SC1, SC2, and SC3, the optical layer OPL, and the active layer ACT may differ from each other. The diameter may mean the average width in a direction perpendicular to the thickness direction DR3.

The optical layer OPL and the active layer ACT may be spaced apart from each other in the thickness direction DR3. Any one of the optical layer OPL and the active layer ACT may be disposed between the first semiconductor layer SC1 and the second semiconductor layer SC2, and another of the optical layer OPL and the active layer ACT may be disposed between the second semiconductor layer SC2 and the third semiconductor layer SC3.

The first to third semiconductor layers SC1, SC2, and SC3 may each include an N-type semiconductor layer or a P-type semiconductor layer. For example, any one of the first to third semiconductor layers SC1, SC2, and SC3 may be a P-type semiconductor layer, and another two of the first to third semiconductor layers SC1, SC2, and SC3 may be N-type semiconductor layers. For example, the N-type semiconductor layer may include at least one semiconductor material of InAlGaN, GaN, AlGaN, InGaN, AlN, and InN, and may be doped with a first conductive dopant such as silicon (Si), germanium (Ge), or tin (Sn). The P-type semiconductor layer may include at least one semiconductor material of InAlGaN, GaN, AlGaN, InGaN, AlN, and InN, and may be doped with a second conductive dopant such as magnesium (Mg), zinc (Zn), calcium (Ca), or barium (Ba). However, this is an example, and the materials composing the N-type semiconductor layer and the P-type semiconductor layer are not limited thereto.

Referring to FIG. 10A, the optical layer OPL may be disposed between the second semiconductor layer SC2 and the third semiconductor layer SC3, and the active layer ACT may be disposed between the first semiconductor layer SC1 and the second semiconductor layer SC2. The second semiconductor layer SC2 and the third semiconductor layer SC3 may each include the N-type semiconductor layer, and the first semiconductor layer SC1 may include the P-type semiconductor layer.

The second semiconductor layer SC2 and the third semiconductor layer SC3, which are spaced apart from each other with the optical layer OPL therebetween, may include the N-type semiconductor layer. The second semiconductor layer SC2 and the third semiconductor layer SC3 may have different dopant concentrations. For example, the dopant concentration with which the second semiconductor layer SC2 is doped may be greater than the dopant concentration with which the third semiconductor layer SC3 is doped. In other embodiments, the second semiconductor layer SC2 and the third semiconductor layer SC3 may be doped with a same dopant concentration.

Referring to FIG. 10B, the optical layer OPL may be disposed between the first semiconductor layer SC1 and the second semiconductor layer SC2, and the active layer ACT may be disposed between the second semiconductor layer SC2 and the third semiconductor layer SC3. The first semiconductor layer SC1 and the second semiconductor layer SC2 may each include the N-type semiconductor layer, and the third semiconductor layer SC3 may include the P-type semiconductor layer. The first semiconductor layer SC1 and the second semiconductor layer SC2, which are spaced apart from each other with the optical layer OPL therebetween, may include the N-type semiconductor layer. The dopant concentrations in the first semiconductor layer SC1 and the second semiconductor layer SC2 may be different from each other.

The active layer ACT may be formed in a single-quantum well or multi-quantum well structure. Electrons and holes may be combined each other in the active layer ACT and emit light in response to electrical signals applied through the P-type semiconductor layer and the N-type semiconductor layer. The active layer ACT may emit light in a wavelength range of about 400 nm to about 900 nm and may use a double hetero-structure.

For example, the active layer ACT may have a structure in which a semiconductor material having large band gap energy and a semiconductor material having small band gap energy are alternately stacked each other. The active layer ACT may also include semiconductor materials of Groups III to V selected according to the wavelength range of light emitted. In this specification, “Group” means a group in the IUPAC periodic table.

Although not illustrated in the drawing, the light-emitting diode LED may further include a clad layer. The clad layer may be disposed above and/or under the active layer ACT. The clad layer may include ALGaN or InAlGaN. The light-emitting diode LED may further include a tensile strain barrier reducing (TSBR) layer disposed above and/or under the active layer ACT. The TSBR layer may be a strain relief layer that is disposed between the semiconductor layers having different lattice structures and serves as a buffer for reducing the difference in lattice constant. The TSBR layer may be formed of the P-type semiconductor layer such as p-GalInP, p-AlInP, and p-AlGaInP. However, an embodiment of the disclosure is not limited thereto.

The optical layer OPL may be disposed between the N-type semiconductor layers. FIG. 11 is a schematic cross-sectional view illustrating an optical layer OPL. Referring to FIG. 11, the optical layer OPL may include a porous layer RL and a non-porous layer NRL disposed on the porous layer RL.

The number of the porous layers RL and the number of the non-porous layers NRL may be n. n is an integer of 1 or more. The number of porous layer RL and the number of non-porous layer NRL may be the same. When n is an integer of 2 or more, the porous layers RL and the non-porous layers NRL may be alternately disposed. For example, n may be 10, and an n-th porous layer RLn, illustrated in FIG. 11, may be a tenth porous layer, and an n-th non-porous layer NRLn may be a tenth non-porous layer. However, this is an example, and the number of the porous layers RL and the number of the non-porous layers NRL are not limited to any one embodiment of the disclosure.

The porous layer RL may include first to n-th porous layers RL₁, RL₂, . . . , and RLₙ. The non-porous layer NRL may include first to n-th non-porous layers NRL₁, . . . , NRLₙ₋₁, and NRLₙ.

In the semiconductor junction structure SJS (e.g., refer to FIGS. 10A and 10B) having a truncated cone shape, a first width (e.g., 1st first width, 2nd first width, . . . , or n-th first width) RW₁, RW₂, . . . , or RWₙ of the porous layer RL may be greater than a second width (e.g., 1st second width, . . . , n−1-th second width, or n-th second width) NW₁, . . . , NWₙ₋₁, or NWₙ of the non-porous layer NRL, respectively. The first width (e.g., 1st first width, 2nd first width, . . . , or n-th first width) RW₁, RW₂, . . . , or RWₙ of the porous layer RL may be greater than the second width (e.g., 1st second width, . . . , n−1-th second width, or n-th second width) NW₁, . . . , NWₙ₋₁, or NWₙ of the non-porous layer NRL disposed above the porous layer RL, respectively. The n-th first width RWₙ of the n-th porous layer RLₙ may be greater than the n-th second width NWₙ of the n-th non-porous layer NRLₙ. The n-th first width RWₙ of the n-th porous layer RLₙ may be smaller than the n−1-th second width NWₙ₋₁ of the n−1-th non-porous layer NRLₙ₋₁. The n−1-th non-porous layer NRLₙ₋₁ may be disposed under the n-th porous layer RLₙ.

The 1st first width RW₁ of the first porous layer RL₁ may be greater than the 1st second width NW₁ of the first non-porous layer NRL₁. The 2nd first width RW₂ of the second porous layer RL₂ may be smaller than the 1st second width NW₁ of the first non-porous layer NRL₁. In a thickness direction (e.g., a third direction or a third directional axis) DR3, the first non-porous layer NRL₁ may be disposed above the first porous layer RL₁, and disposed under the second porous layer RL₂.

In the thickness direction DR3, the width may decrease from a lower side to an upper side of the optical layer OPL. Compared to the second width (e.g., 1st second width, . . . , n−1-th second width, or n-th second width) NW₁, . . . , NWₙ₋₁, or NWₙ of the non-porous layer NRL disposed in the upper side in the thickness direction DR3, the first width (e.g., 1st first width, 2nd first width, . . . , or n-th first width) RW₁, RW₂, . . . , or RWₙ of the porous layer RL disposed in the lower side, in the thickness direction DR3, may be relatively large.

The porous layer RL and the non-porous layer NRL may include a Group III-N (e.g., nitrogen atom) semiconductor compound, and may be doped with a first conductive dopant such as silicon (Si), germanium (Ge), or tin (Sn). For example, the porous layer RL and the non-porous layer NRL may each include at least one semiconductor material of gallium nitride (GaN), indium gallium nitride (InGaN), and aluminum gallium nitride (AlGaN), and may be doped with the first conductive dopant such as silicon (Si), germanium (Ge), or tin (Sn).

The porous layer RL and the non-porous layer NRL may each include the same semiconductor material as that of any two of the first to third semiconductor layers SC1, SC2, and SC3 (e.g., refer to FIGS. 10A and 10B). The porous layer RL and the non-porous layer NRL may each include the same semiconductor material as that of the N-type semiconductor layer of the first to third semiconductor layers SC1, SC2, and SC3 (e.g., refer to FIGS. 10A and 10B). The optical layer OPL composed of the porous layer RL and the non-porous layer NRL may be inserted in the N-type semiconductor layer. However, this is an example, and an embodiment of the disclosure is not limited thereto.

A dopant of the porous layer RL and a dopant of the non-porous layer NRL may be different from each other in doping concentration. The concentration of the dopant with which the porous layer RL is doped may be relatively greater than the concentration of the dopant with which the non-porous layer NRL is doped. In a method for manufacturing a display device according to an embodiment, the optical layer OPL may be formed through an electro-chemical (EC) etching process. Detailed description of the method for manufacturing the display device is provided below. By the electro-chemical etching process, the optical layer OPL including the porous layer RL and the non-porous layer NRL may be formed. In case that the electro-chemical etching process is performed, a porous structure may be formed at a portion of the optical layer OPL with relatively high doping concentration to form the porous layer RL, and the porous structure may not be formed at another portion of the optical layer OPL with relatively low doping concentration to form the non-porous layer NRL. For example, the porous layer RL and the non-porous layer NRL may be formed through the electro-chemical etching process, and the porous layer RL may have greater concentration than the non-porous layer NRL. Since the porous structure is formed, point defects may be reduced, leakage current of the light-emitting diode LED (e.g., refer to FIG. 6) may be prevented, and light efficiency of the light-emitting diode LED (e.g., refer to FIG. 6) may be improved.

A thickness (e.g., 1st thickness, 2nd thickness, . . . , or n-th thickness) RH₁, RH₂, . . . , or RHₙ of the porous layer (e.g., 1st porous layer, 2nd porous layer, . . . , or n-th porous layer) RL₁, RL₂, . . . , or RLₙ may satisfy Equation 1 below. A thickness (e.g., 1st thickness, . . . , n−1-th thickness, or n-th thickness) NH₁ . . . , NHₙ₋₁, or NHₙ of the non-porous layer NRL₁, . . . , NRLₙ₋₁, or NRLₙ may satisfy Equation 2 below.

$${T}_{1} = {λ}_{0} / 4 {n}_{1} \qquad [ Equation 1 ]$$

$${T}_{2} = {λ}_{0} / 4 {n}_{2} \qquad [ Equation 2 ]$$

In Equation 1, n₁ may be the refractive index of the porous layer RL, and T₁ may be the thickness (e.g., 1st thickness, 2nd thickness, . . . , or n-th thickness) RH₁, RH₂, . . . , or RHₙ of the porous layer (e.g., 1st porous layer, 2nd porous layer, . . . , or n-th porous layer) RL₁, RL₂, . . . , or RLₙ. In Equation 2, n₂ may be the refractive index of the non-porous layer NRL, and T₂ may be the thickness (e.g., 1st thickness, . . . , n−1-th thickness, or n-th thickness) NH₁, . . . , NHₙ₋₁, or NHₙ of the non-porous layer NRL₁, . . . , NRLₙ₋₁, or NRLₙ. In Equation 1 and Equation 2, λ₀ may be the wavelength of light emitted from the active layer ACT (e.g., refer to FIG. 10A or 10B).

The thickness (e.g., 1st thickness, . . . , n−1-th thickness, or n-th thickness) NH₁, . . . , NHₙ₋₁, or NHₙ of the non-porous layer NRL₁, . . . , NRLₙ₋₁, or NRLₙ may be about 2m₀+1 (where m₀ is an integer of 0 or more) times the thickness (e.g., 1st thickness, . . . , n−1-th thickness, or n-th thickness) RH₁, RH₂, . . . , or RHₙ of the porous layer (e.g., 1st porous layer, 2nd porous layer, . . . , or n-th porous layer) RL₁, RL₂, . . . , or RLₙ. For example, in case that m₀ is 0, the thickness (e.g., 1st thickness, . . . , n−1-th thickness, or n-th thickness) NH₁, . . . , NHₙ₋₁, or NHₙ of the non-porous layer NRL₁, . . . , NRLₙ₋₁, or NRLₙ and the thickness (e.g., 1st thickness, . . . , n−1-th thickness, or n-th thickness) RH₁, RH₂, . . . , or RHₙ of the porous layer (e.g., 1st porous layer, 2nd porous layer, . . . , or n-th porous layer) RL₁, RL₂, . . . , or RLₙ may be the same. In other embodiments, in case that m₀ is 1, the thickness (e.g., 1st thickness, . . . , n−1-th thickness, or n-th thickness) NH₁, . . . , NHₙ₋₁, or NHₙ of the non-porous layer NRL₁, . . . , NRLₙ₋₁, or NRLₙ may be about three times the thickness RH₁, RH₂, . . . , or RHₙ (e.g., 1st thickness, . . . , n−1-th thickness, or n-th thickness) of the porous layer (e.g., 1st porous layer, 2nd porous layer, . . . , or n-th porous layer) RL₁, RL₂, . . . , or RLₙ.

The thickness of the optical layer OPL, which is the sum of the 1st to n-th thicknesses RH₁, RH₂, . . . , and RHₙ of the 1st to n-th porous layers RL₁ to RLₙ and the 1st, . . . , n−1-th, and n-th thicknesses NH₁, . . . , NHₙ₋₁, and NHₙ of the 1st, . . . , n−1-th, and n-th non-porous layers NRL₁, . . . , NRLₙ₋₁, and NRLₙ may be in a range of about 600 nm to about 1200 nm. The light-emitting diode LED (e.g., refer to FIG. 6) including the optical layer OPL having a thickness in a range of about 600 nm to about 1200 nm may exhibit excellent light efficiency without increasing the thickness of the display device DD (e.g., refer to FIG. 1).

The optical layer OPL may include layers having different refractive indexes. A first refractive index of the porous layer RL may be smaller than a second refractive index of the non-porous layer NRL. Since the porous layer RL (e.g., the 1st porous layer RL₁, . . . , and the n-th porous layer RLₙ) and the non-porous layer NRL (e.g., the 1st non-porous layer NRL₁, . . . , and the n-th non-porous layer NRLₙ) are alternately disposed, the optical layer OPL may have a structure in which a layer having a relatively small refractive index and a layer having a relatively large refractive index are alternately disposed.

The optical layer OPL may be a reflector provided to reflect light. The optical layer OPL may be a distributed Bragg reflector (DBR). The optical layer OPL may have a reflectance (e.g., a predetermined or selectable reflectance). For example, the reflectance of the optical layer OPL may be close to the reflectance of metal. For example, the reflectance of the optical layer OPL with respect to light in a visible light wavelength range may be in a range of about 80% to about 95%. In case that the number of porous layer RL and the number of non-porous layer NRL increase, the reflectance may increase.

Light emitted from the active layer ACT may be provided to the optical layer OPL. Thus, since refractive index between the porous layer RL and the non-porous layer NRL included in the optical layer OPL are different from each other, reflection of the light provided from the active layer ACT may occur on an interface between the porous layer RL and the non-porous layer NRL. The porous layer RL (e.g., the 1st porous layer RL₁, . . . , and the n-th porous layer RLₙ) and the non-porous layer NRL (e.g., the 1st non-porous layer NRL₁, . . . , and the n-th non-porous layer NRLₙ) may be alternately disposed each other on the optical layer OPL, the interface between adjacent ones of the porous layer RL and the non-porous layer NRL may exist in plurality. Constructive interference of the reflected light may be generated on the interface, and optical loss may be prevented. Accordingly, the light-emitting diode LED (e.g., refer to FIG. 6), including the optical layer OPL composed of the porous layer RL and the non-porous layer NRL, may exhibit excellent light efficiency. The display device DD (e.g., refer to FIG. 1) including the light-emitting diode LED (e.g., refer to FIG. 6) may provide excellent display quality.

Directional light emission may be required for a display device adopted to (e.g., included in) an augmented reality apparatus. In other embodiments, the display device of the augmented reality apparatus may include a light-emitting diode having a resonance structure, and the manufacturing of the resonance structure may include depositing a reflection layer to upper/lower sides of the light-emitting diode. Thus, light efficiency may be lowered due to high-order resonance caused by the thickness increase of the light-emitting diode.

In case that a microscale light-emitting diode disposed on a silicon substrate does not include an optical layer composed of the porous layer and the non-porous layer, only high-order resonance of about 8th or higher may be possible. In case of the high-order resonance, effect of improved light-efficiency by resonance may be lowered, and relatively long cavity length may be required. The cavity length may be parallel to the thickness direction of the light-emitting diode, and the long cavity length may increase the thickness of the light-emitting diode. In other embodiments, a light-emitting diode may have a cavity length ranging from a first transparent conductive oxide layer COL (e.g., refer to FIG. 11) of a first electrode part ES1 to the third semiconductor layer SC3 (e.g., refer to FIG. 10A). Detailed description of the first transparent conductive oxide layer COL of the first electrode part ES1 is provided below.

In other embodiments, the thickness of an N-type semiconductor layer may be decreased for low-order resonance with a relatively low order. However, in case that the thickness of the N-type semiconductor layer is decreased, process variation of the N-type semiconductor layer which is formed by an etching process may be increased.

However, in the embodiment of the disclosure, the light-emitting diode LED may include the optical layer OPL composed of the porous layer RL and the non-porous layer NRL. Thus, the light-emitting diode LED may include a cavity length ranging from the first transparent conductive oxide layer COL (e.g., refer to FIG. 11) of the first electrode part ES1 to the second semiconductor layer SC2 (e.g., refer to FIG. 10A). For example, the cavity length of the light-emitting diode LED of the embodiment of the disclosure may be increased by the optical layer OPL composed of the porous layer RL and the non-porous layer NRL without an increase in thickness. Detailed description of the first transparent conductive oxide layer COL of the first electrode part ES1 is provided below. Accordingly, the light-emitting diode LED, according to an embodiment, may have the characteristic that low-order resonance is possible. The light-emitting diode LED, according to an embodiment, may exhibit excellent light efficiency without an increase in thickness.

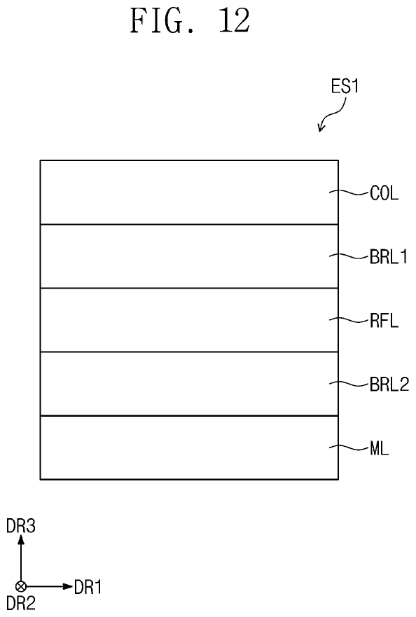

FIG. 12 is a schematic cross-sectional view illustrating the first electrode part ES1 in FIG. 6. Referring to FIG. 12, the first electrode part ES1 may include a reflection layer RFL and a transparent conductive oxide layer COL (hereinafter, referred to as a first transparent conductive oxide layer) disposed on the reflection layer RFL. The first electrode part ES1 may further include a first barrier layer BRL1 disposed between the reflection layer RFL and the first transparent conductive oxide layer COL, a second barrier layer BRL2 disposed under the reflection layer RFL, and a metal layer ML disposed under the second barrier layer BRL2. However, the disclosure is not limited thereto, and the first electrode part ES1 may also further include an additional functional layer such as a third barrier layer disposed under the metal layer ML.

The reflection layer RFL may reflect light generated from the active layer ACT (e.g., refer to FIGS. 10A and 10B) in a direction toward a semiconductor junction structure SJS (e.g., refer to FIGS. 10A and 10B). The reflection layer RFL may include at least one of gold (Au), copper (Cu), silver (Ag), titanium (Ti), and aluminum (Al). However, the disclosure is not limited thereto. For example, the reflection layer RFL may have a reflectance of about 90% for light in a visible light wavelength range.

In case that the first electrode part ES1 is an anode, the first transparent conductive oxide layer COL may inject holes to the semiconductor junction structure SJS. The first transparent conductive oxide layer COL may have high work function, which is advantageous to the hole injection, and may transmit the light reflected on the reflection layer RFL. The first transparent conductive oxide layer COL may include at least one of indium tin oxide (ITO), indium zinc oxide (IZO), zinc oxide (ZnO), zinc tin oxide (ZTO), and indium gallium zinc oxide (IGZO). However, the disclosure is not limited thereto.

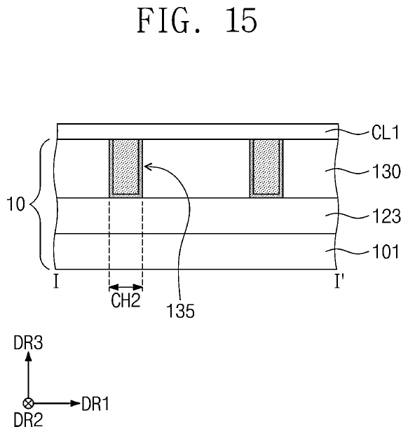

The metal layer ML may correspond to an adhesion layer that bonds a CMOS wafer 10 (e.g., refer to FIG. 15) and a semiconductor substrate SUB-S (e.g., refer to FIG. 15) during a display device manufacturing process. The metal layer ML may be formed by bonding a metal layer of the CMOS wafer 10 (e.g., refer to FIG. 15) to a metal layer of the semiconductor substrate SUB-S (e.g., refer to FIG. 15). The metal layer ML may include a single layer or multiple layers. The metal layer ML may include at least one metal layer. The at least one metal layer may include at least one of gold (Au), copper (Cu), silver (Ag), tin (Sn), titanium (Ti), zirconium (Zr), and tantalum (Ta). For example, the at least one metal layer may include an alloy of two metals thereof. However, the disclosure is not limited thereto.

The first and second barrier layers BRL1 and BRL2 may each include a barrier metal layer and a barrier-metal nitride layer. The barrier metal layer may improve adhesive strength between adjacent layers, and the barrier-metal nitride layer may prevent diffusion of atoms between the adjacent layers.

The first barrier layer BRL1 may include a single layer or multiple layers. For example, the first barrier layer BRL1 may include the barrier-metal nitride layer containing titanium nitride, and the barrier metal layers containing titanium and disposed on each of the upper side and the lower side of the barrier-metal nitride layer. The titanium nitride layer may block movement of metal atoms. Thus, occurrence of electro-migration between adjacent layers may be prevented.

The second barrier layer BRL2 may include a single layer or multiple layers. For example, the second barrier layer BRL2 may include the barrier-metal nitride layer containing titanium nitride. For example, the titanium nitride layer may block movement of atoms between the first transparent conductive oxide layer COL and the reflection layer RFL. Thus, formation of void on the first transparent conductive oxide layer COL or oxidization of the reflection layer RFL may be prevented.

Referring to FIGS. 10A and 10B again, the second electrode part ES2 may include a transparent conductive oxide layer (hereinafter, referred to as a second transparent conductive oxide layer). The second transparent conductive oxide layer may include at least one of indium tin oxide (ITO), indium zinc oxide (IZO), zinc oxide (ZnO), zinc tin oxide (ZTO), and indium gallium zinc oxide (IGZO). However, the disclosure is not limited thereto. The second transparent conductive oxide layer may correspond to a protection layer in a light-emitting diode (LED) manufacturing process and may inject electrons to the semiconductor junction structure SJS.

The second electrode part ES2 may further include an electrode metal layer disposed between the second transparent conductive oxide layer and the semiconductor junction structure SJS. The electrode metal layer may include metal having a lower work function than that of the second transparent conductive oxide layer. The electrode metal layer may improve electron-injection quality of the second electrode part ES2. The electrode metal layer may include at least one of aluminum (Al), titanium (Ti), indium (In), gold (Au), silver (Ag), nickel (Ni), and copper (Cu). For example, the electrode metal layer may include an oxide thereof, or an alloy thereof. However, the disclosure is not limited thereto.

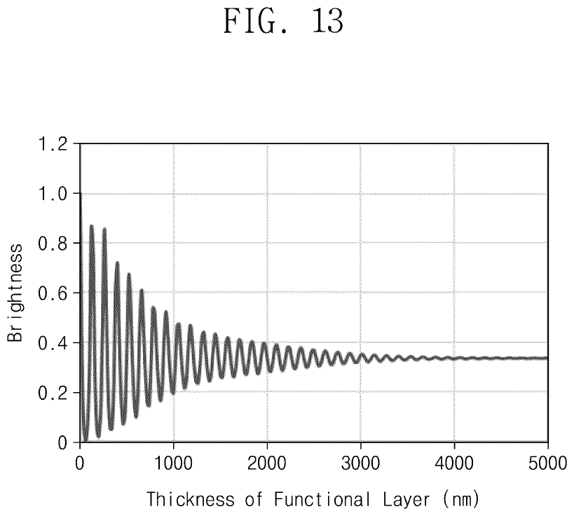

FIG. 13 is a graph schematically showing the relative value of brightness according to the thickness of a functional layer in a light-emitting diode including the functional layer that injects holes. The graph in FIG. 13 shows the result of simulation.

Referring to FIG. 13, the brightness may increase as the thickness of the functional layer decreases. Brightness may be improved in the low-order resonance. Therefore, the light-emitting diode according to an embodiment may include an optical layer composed of a porous layer and a non-porous layer, and the light-emitting diode may have excellent light efficiency without an increase in thickness.

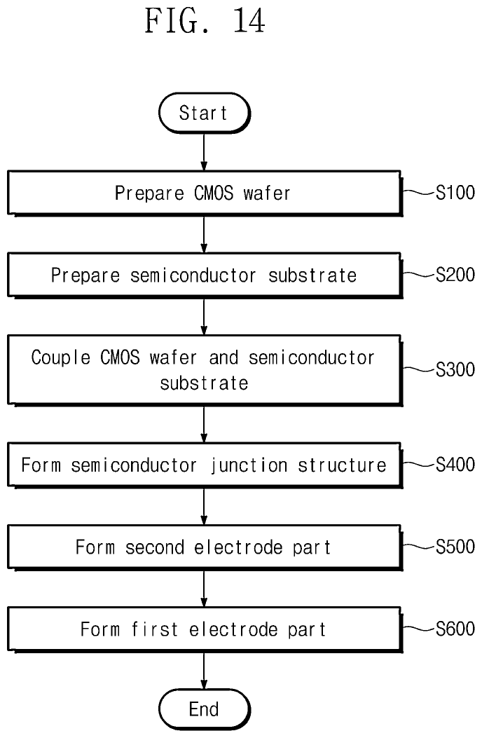

A display device according to an embodiment may be manufactured in a method for manufacturing a display device according to an embodiment. FIG. 14 is a flowchart schematically illustrating the method for manufacturing the display device according to an embodiment. FIGS. 15 to 29 are drawings schematically illustrating manufacturing steps of the display device according to an embodiment. Hereinafter, for the description with reference to FIGS. 14 to 29, detailed description of the same constituent elements described with reference to FIGS. 1 to 13 is omitted.

Referring to FIG. 14, the method for manufacturing the display device according to an embodiment may include preparing a CMOS wafer including a first silicon substrate and a conductive layer disposed on the first silicon substrate (S100), preparing a semiconductor substrate including a preliminary semiconductor junction structure and a second silicon substrate disposed on the preliminary semiconductor junction structure (S200), coupling the CMOS wafer and the semiconductor substrate (S300), dry etching the preliminary semiconductor junction structure to form a semiconductor junction structure (S400), forming a second electrode part (S500), and forming a first electrode part (S600).

Referring to FIG. 15, the CMOS wafer 10 may include a first silicon substrate 101, a first insulation layer 123, and a second insulation layer 130 stacked one another in sequence. A first conductive layer CL1 may be disposed on the CMOS wafer 10. The CMOS wafer in FIG. 15 is illustrated more simply than the CMOS wafer 10 in FIG. 6, except for a second contact electrode 135 disposed in a second contact hole CH2, and for ease of description. Thus, detailed description of the same constituent elements is omitted.

For example, the first conductive layer CL1 may be formed through a deposition process, and the type of the deposition process is not limited thereto. The first conductive layer CL1 may include at least one metal layer. The first conductive layer CL1 may include the metal layer ML illustrated in FIG. 12.

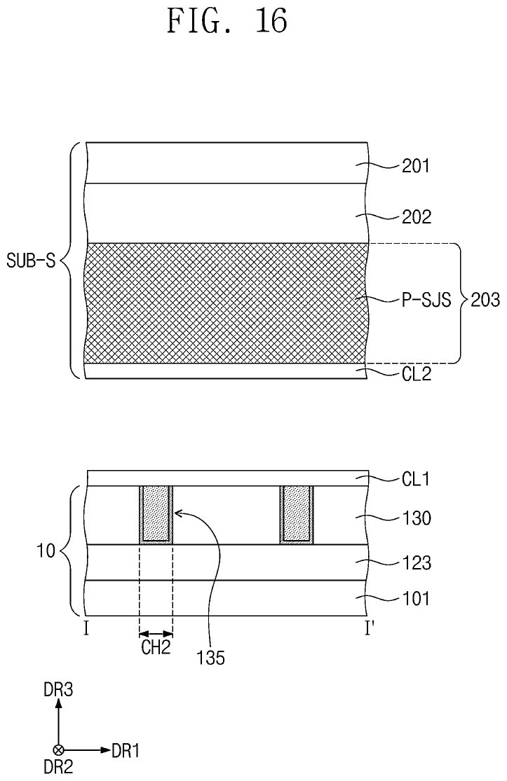

Referring to FIG. 16, the semiconductor substrate SUB-S may be provided onto the CMOS wafer 10. The semiconductor substrate SUB-S may be aligned with the CMOS wafer 10.

The semiconductor substrate SUB-S may include a second silicon substrate 201, a buffer layer 202 disposed under the second silicon substrate 201, a semiconductor junction layer 203 disposed under the buffer layer 202, and a second conductive layer CL2 disposed under the semiconductor junction layer 203. The buffer layer 202 may be an epitaxial layer grown from the second silicon substrate 201.

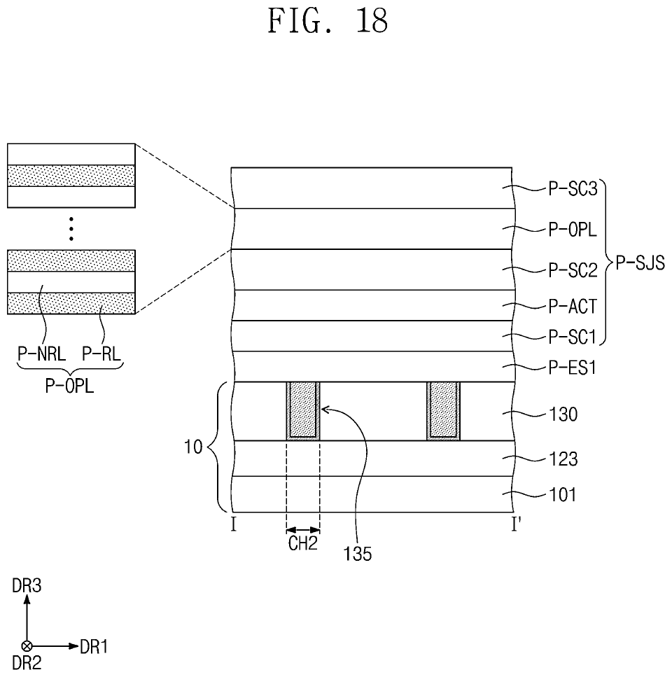

The semiconductor junction layer 203 may include the preliminary semiconductor junction structure P-SJS. The semiconductor junction structure SJS (e.g., refer to FIGS. 10A and 10B) may be formed from the preliminary semiconductor junction structure P-SJS. In the semiconductor junction layer 203, the thickness of a preliminary third semiconductor layer P-SC3 (e.g., refer to FIG. 18), included in the preliminary semiconductor junction structure P-SJS, may be greater than the thickness of the third semiconductor layer SC3 (e.g., refer to FIGS. 10A and 10B) included in the semiconductor junction structure SJS (e.g., refer to FIGS. 10A and 10B). In a grinding process, a portion of the preliminary third semiconductor layer P-SC3 (e.g., refer to FIG. 18) may be removed. Detailed description of the grinding process is provided below.

The second conductive layer CL2 may include a transparent conductive oxide layer, a reflection layer disposed under the transparent conductive oxide layer, and at least one metal layer disposed above the reflection layer. The second conductive layer CL2 may include at least one of the first transparent conductive oxide layer COL (e.g., refer to FIG. 12), the reflection layer RFL (e.g., refer to FIG. 12), and the metal layer ML (e.g., refer to FIG. 12). The second conductive layer CL2 may further include at least one of the first and second barrier layers BRL1 and BRL2 (e.g., refer to FIG. 12).

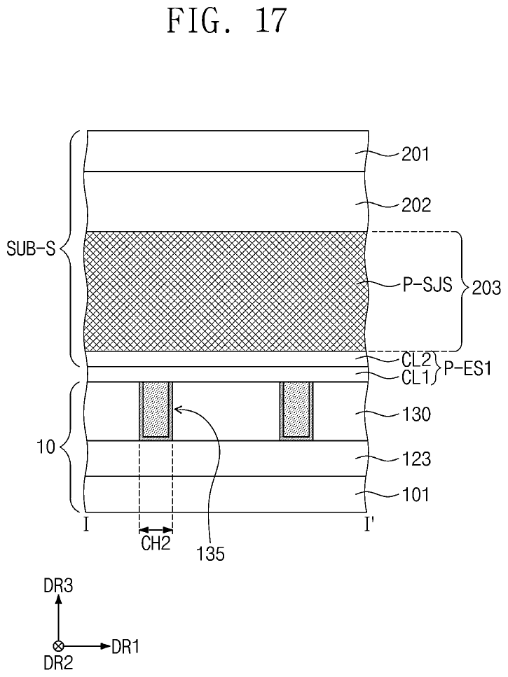

Referring to FIG. 17, the CMOS wafer 10 and the semiconductor substrate SUB-S may be coupled to each other. The second conductive layer CL2 may be bonded to the first conductive layer CL1 by high-temperature and high-pressure processes. The second conductive layer CL2 may be bonded to the first conductive layer CL1. Thus, a preliminary first electrode part P-ES1 may be formed. In FIG. 18, the preliminary first electrode part P-ES1 may be a single layer. However, the disclosure is not limited thereto, and the preliminary first electrode part P-ES1 may have multiple layers.

After the second conductive layer CL2 is bonded to the first conductive layer CL1, a portion of the semiconductor junction layer 203 may be removed. The portion of the semiconductor junction layer 203 may be removed by a grinding process of a semiconductor. In the grinding process, the second silicon substrate 201 and the buffer layer 202 may be removed (e.g., completely removed), and the portion of the semiconductor junction layer 203 may be removed.

Referring to FIG. 18, the preliminary semiconductor junction structure P-SJS may include a preliminary first semiconductor layer P-SC1, a preliminary active layer P-ACT, a preliminary second semiconductor layer P-SC2, a preliminary optical layer P-OPL, and a preliminary third semiconductor layer P-SC3 which are stacked one another in sequence. The light-emitting diode LED illustrated in FIG. 10A may be formed from the preliminary semiconductor junction structure P-SJS illustrated in FIG. 18.

However, the disclosure is not limited thereto, and the preliminary optical layer P-OPL may be disposed between the preliminary first semiconductor layer P-SC1 and the preliminary second semiconductor layer P-SC2, and the preliminary active layer P-ACT may be disposed between the preliminary second semiconductor layer P-SC2 and the preliminary third semiconductor layer P-SC3. Thus, the light-emitting diode LED illustrated in FIG. 10B may be formed.

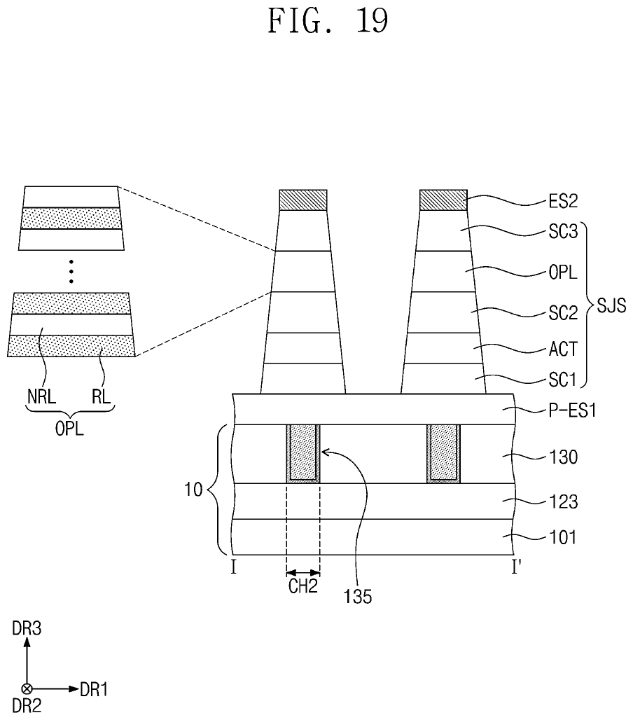

The preliminary optical layer P-OPL may include a preliminary porous layer P-RL and a preliminary non-porous layer P-NRL. For example, the preliminary optical layer P-OPL may include multiple preliminary porous layers P-RL and multiple preliminary non-porous layers P-NRL. The preliminary porous layers P-RL and the preliminary non-porous layers P-NRL may be alternately disposed with each other. The concentration of a dopant with which the preliminary porous layer P-RL is doped may be greater than the concentration of a dopant with which the preliminary non-porous layer P-NRL is doped. Since the concentration of the dopant is higher, the speed of an electro-chemical etching process may become higher. Accordingly, in the electro-chemical etching process, the preliminary porous layer P-RL may be formed into a porous layer RL (e.g., refer to FIG. 19) having a porous structure, and the preliminary non-porous layer P-NRL may be formed into a non-porous layer NRL (e.g., refer to FIG. 19) not having a porous structure. Detailed description of the electro-chemical etching process is provided below.

A semiconductor junction structure SJS may be formed by the dry etching of the preliminary semiconductor junction structure P-SJS. Referring to FIGS. 18 and 19, a first semiconductor layer SC1 may be formed from the preliminary first semiconductor layer P-SC1, a second semiconductor layer SC2 may be formed from the preliminary second semiconductor layer P-SC2, and a third semiconductor layer SC3 may be formed from the preliminary third semiconductor layer P-SC3. An active layer ACT may be formed from the preliminary active layer P-ACT.

After the dry-etching process of the preliminary semiconductor junction structure P-SJS is performed, an electro-chemical etching process may be performed on the preliminary optical layer P-OPL. Thus, an optical layer OPL may be formed. The electro-chemical etching process may be performed through a side surface of the preliminary optical layer P-OPL on which the dry-etching process has been performed. The electro-chemical etching process may be performed on the preliminary optical layer P-OPL including the side surface exposed through the dry-etching process. For example, in case that the electro-chemical etching process is performed, a potassium hydroxide (KOH) or nitric acid (HNO₃) solution may be provided. However, an embodiment of the disclosure is not limited thereto.

The semiconductor junction structure SJS, formed through the dry-etching process, may have a width decreasing from a lower side to an upper side. The width may mean a width in a direction (e.g., a first direction or a first directional axis) DR1 perpendicular to a thickness direction (e.g., a third direction or a third directional axis) DR3. Accordingly, in the optical layer OPL, the first width (e.g., 1st first width, 2nd first width, . . . , or n-th first width) RW₁, RW₂, . . . , or RWₙ (e.g., refer to FIG. 11) of the porous layer (e.g., 1st porous layer RL₁, 2nd porous layer RL₂, . . . , or n-th porous layer RLₙ) RL (e.g., refer to FIG. 11), disposed on the lower side, may be greater than the second width (e.g., 1st second width, . . . , n−1-th second width, or n-th second width) NW₁, . . . , NWₙ₋₁, or NWₙ (e.g., refer to FIG. 11) of the non-porous layer (e.g., 1st non-porous layer NRL₁, 2nd non-porous layer NRL₂, . . . , or n-th non-porous layer NRLₙ) NRL (e.g., refer to FIG. 11) disposed on the upper side. For example, each of the 1st to n-th non-porous layers NRL₁ to NRLₙ may be disposed on each of the 1st to n-th porous layers RL₁ to RLₙ.

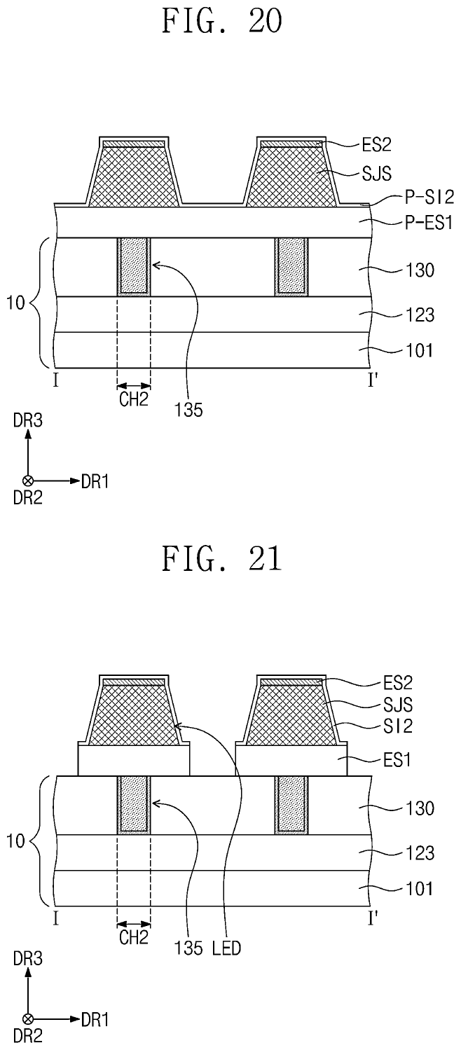

The second electrode part ES2 may be formed on the semiconductor junction structure SJS. After the forming of the semiconductor junction structure SJS, the second electrode part ES2 may be formed. In other embodiments, the forming of the second electrode part ES2 and the forming of the semiconductor junction structure SJS may be performed in a same process. For example, a preliminary second electrode part may be formed on the preliminary semiconductor junction structure P-SJS, and the second electrode part ES2 may be formed from the preliminary second electrode part in the forming of the semiconductor junction structure SJS from the preliminary semiconductor junction structure P-SJS. In FIG. 20, the semiconductor junction structure SJS may be a single layer. However, the disclosure is not limited thereto, and the semiconductor junction structure SJS may have multiple layers.

Referring to FIG. 20, a preliminary second side-surface insulation layer P-SI2 may be formed on the CMOS wafer 10. The preliminary second side-surface insulation layer P-SI2 may be formed through a deposition process of an inorganic material. The preliminary second side-surface insulation layer P-SI2 may be disposed on the preliminary first electrode part P-ES1 and surround side surfaces of the semiconductor junction structures SJS and the second electrode part ES2. The preliminary second side-surface insulation layer P-SI2 may be disposed on an upper surface of the second electrode part ES2.

In FIG. 21, the preliminary second side-surface insulation layer P-SI2 (e.g., refer to FIG. 20) and the preliminary first electrode part P-ES1 (e.g., refer to FIG. 20) may be patterned. Thus, the light-emitting diodes LED may be formed. The second side-surface insulation layer SI2, illustrated in FIG. 6, may be formed from the preliminary second side-surface insulation layer P-SI2, and the first electrode part ES1, illustrated in FIG. 6, may be formed from the preliminary first electrode part P-ES1. In other embodiments, in case that the forming of the preliminary second side-surface insulation layer P-SI2 is omitted, the second side-surface insulation layer SI2 (e.g., refer to FIG. 6) may not be formed.

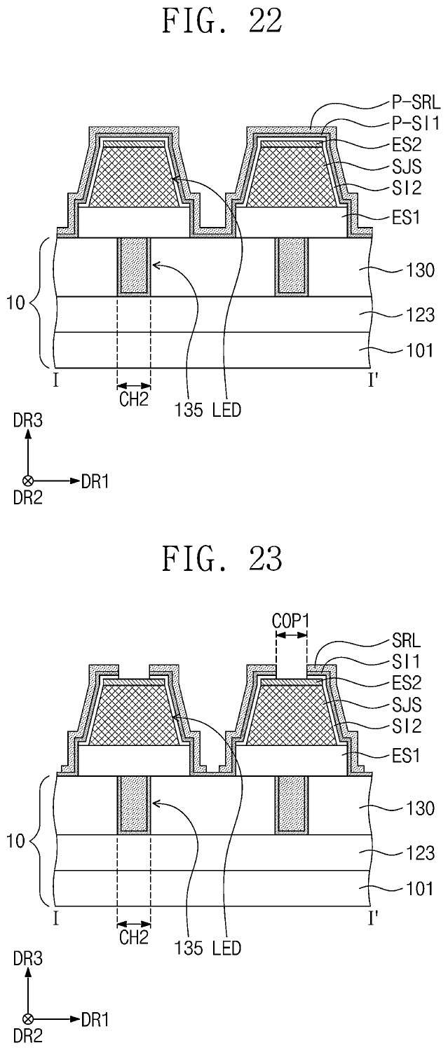

Referring to FIG. 22, a preliminary first side-surface insulation layer P-SI1 may be formed on the CMOS wafer 10. A preliminary side-surface reflection layer P-SRL may be formed on the preliminary first side-surface insulation layer P-SI1.

The preliminary first side-surface insulation layer P-SI1 may be formed through a deposition process of an inorganic material. The preliminary first side-surface insulation layer P-SI1 may be disposed on the second side-surface insulation layer SI2, and cover the side surface of the first electrode part ES1. The preliminary first side-surface insulation layer P-SI1 may be disposed in a partial region of an upper surface of the CMOS wafer 10.

The preliminary side-surface reflection layer P-SRL may be formed by depositing metal. For example, the preliminary side-surface reflection layer P-SRL may be formed by depositing at least one of gold (Au), copper (Cu), silver (Ag), titanium (Ti), and aluminum (Al). However, the disclosure is not limited thereto. The preliminary side-surface reflection layer P-SRL may be disposed and the preliminary first side-surface insulation layer P-SI1 may be covered by the preliminary side-surface reflection layer P-SRL.

Referring to FIGS. 22 and 23, the preliminary first side-surface insulation layer P-SI1 may be patterned and a first side-surface insulation layer SI1 may be formed. The preliminary side-surface reflection layer P-SRL may be patterned and a side-surface reflection layer SRL may be formed. A first opening COP1, which passes through the first side-surface insulation layer SI1 and the side-surface reflection layer SRL, may be formed. For example, the first side-surface insulation layer SI1 and the side-surface reflection layer SRL may be wet-etched to form the first opening COP1. In the wet-etching process that forms the first opening COP1, the second transparent conductive oxide layer of the second electrode part ES2 may protect the semiconductor junction structure SJS disposed thereunder from an etchant. For example, the second transparent conductive oxide layer of the second electrode part ES2 may be an etch stop layer against the wet-etching.

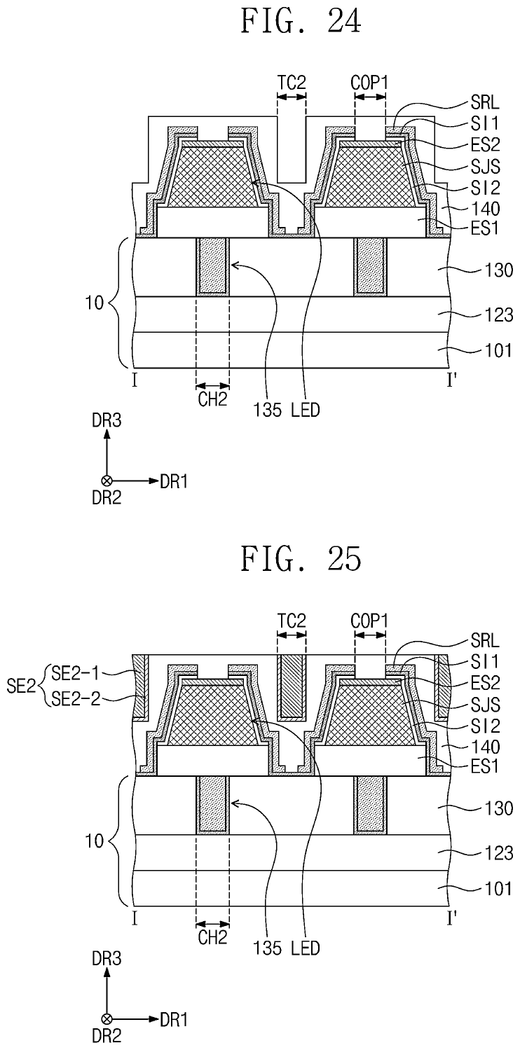

Referring to FIG. 24, a planarization layer 140, in which a second trench TC2 is defined, may be formed. The planarization layer 140 formed of an organic material may be formed on the CMOS wafer 10 through an inkjet process or coating process. The second trench TC2 may be formed in the planarization layer 140 through a photolithography process. Although not illustrated in the drawing, in case that the second trench TC2 is formed, the first trench TC1, illustrated in FIG. 5, may also be formed together.

Referring to FIG. 25, a second auxiliary electrode SE2 may be formed in the second trench TC2. Although not illustrated in the drawing, in case that the second auxiliary electrode SE2 is formed, the first auxiliary electrode SE1, illustrated in FIG. 5, may also be formed together.

The second auxiliary electrode SE2 may be formed through a damascene method. After a barrier layer is formed thinly on the planarization layer 140 through the first deposition process, a metal layer may have a greater thickness than the barrier layer through the second deposition process. The barrier layer and the metal layer (e.g., portions of the barrier layer and the metal layer), disposed on the planarization layer 140, may be removed through a CMP process. Accordingly, the second auxiliary electrode SE2 including a barrier layer SE2-2 and a metal structure SE2-1 may be disposed only inside the second trench TC2.

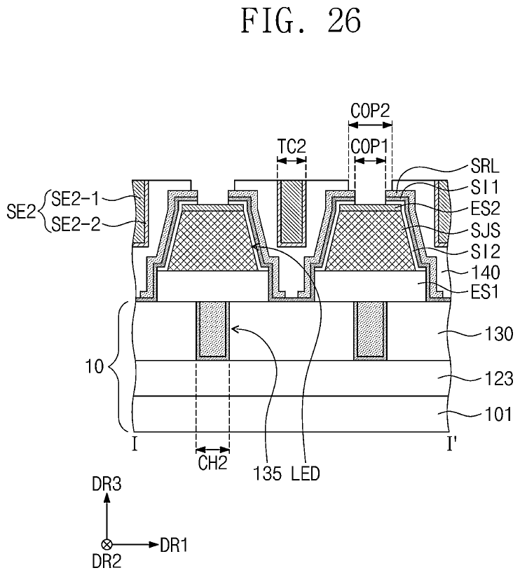

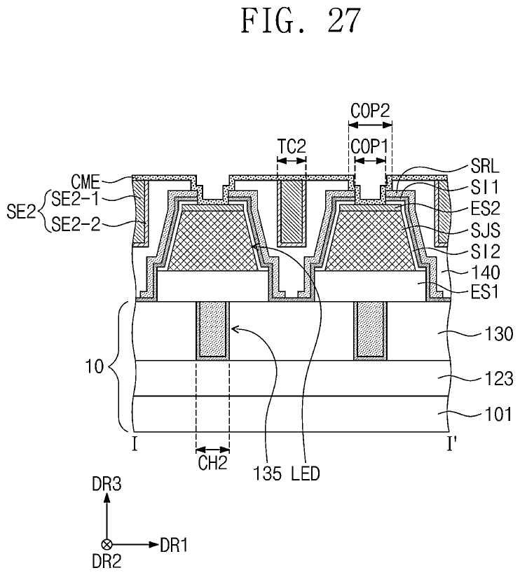

As illustrated in FIG. 26, a second opening COP2 may be formed in the planarization layer 140. The second openings COP2 may correspond to the first openings COP1, and a partial region of the second electrode part ES2 may be exposed to the outside. The second openings COP2 each may have a greater diameter than that of each of the first openings COP1. However, an embodiment of the disclosure is not limited thereto.

Referring to FIG. 27, a common electrode CME may be formed on the planarization layer 140. The transparent conductive oxide layer may be formed and patterned on the planarization layer 140 to form the common electrode CME. Although not illustrated in the drawing, the voltage transmission electrode VTE (e.g., refer to FIGS. 3 and 4) may have an integrated shape with the common electrode CME. For example, the voltage transmission electrode VTE and the common electrode CME may be simultaneously formed through a same process.

The common electrode CME and the voltage transmission electrode VTE in the integrated shape may be formed through a photolithography process. The common electrode CME may be electrically connected to the light-emitting diode LED through the first opening COP1 and the second opening COP2.

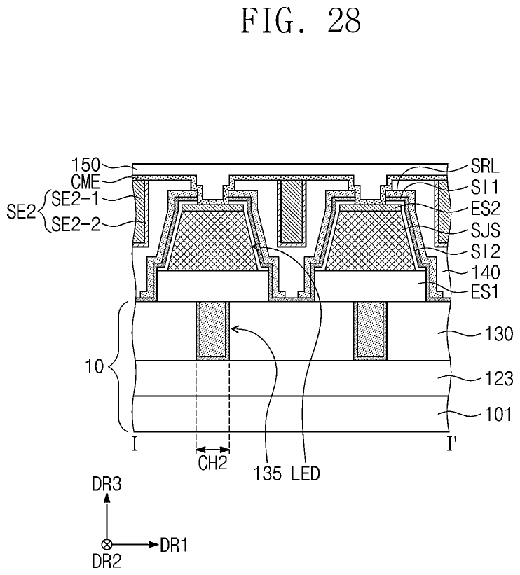

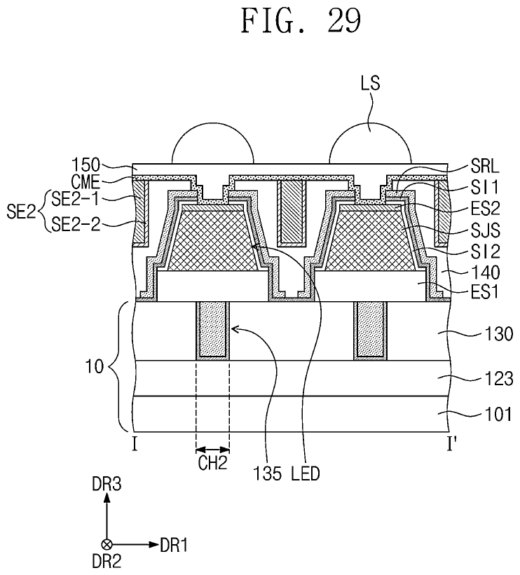

Referring to FIG. 28, a third insulation layer 150 covering the common electrode CME may be formed on the planarization layer 140. Referring to FIG. 29, lenses LS may be formed on the third insulation layer 150. The lenses LS may overlap the light-emitting diodes LED. An organic layer may be patterned through a photolithography process and the lenses LS may be formed. In other embodiments, an organic material may be provided through an inkjet process and dried to form the lenses LS.

A method for manufacturing a display device according to an embodiment may include forming a semiconductor junction structure by a dry-etching process. The display device according to an embodiment, may be manufactured by the method for manufacturing the display device according to an embodiment and include a light-emitting diode. In an embodiment, the light-emitting diode may include the semiconductor junction structure, and the semiconductor junction structure may include an optical layer disposed between adjacent ones of the semiconductor layers. The optical layer may include a porous layer and a non-porous layer disposed on the porous layer, and a first width of the porous layer in a direction perpendicular to the thickness direction may be greater than a second width of the non-porous layer. In case that the light-emitting diode may include the porous layer and the non-porous layer, the light-emitting diode may have low-order resonance without an increase in thickness. Accordingly, the light-emitting diode according to an embodiment may exhibit excellent light efficiency, and the display device according to an embodiment may provide excellent display quality.

A light-emitting diode according to an embodiment may include a semiconductor junction structure having a porous layer and a non-porous layer and exhibit excellent light efficiency.

A display device according to an embodiment may be manufactured in a method for manufacturing a display device according to an embodiment which includes forming a semiconductor junction structure. Thus, the display device may have excellent display efficiency.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A light-emitting diode comprising:
a first electrode part;
a second electrode part disposed on the first electrode part; and
a semiconductor junction structure disposed between the first electrode part and the second electrode part, wherein
the semiconductor junction structure includes:
a first semiconductor layer;
a second semiconductor layer disposed on the first semiconductor layer;
a third semiconductor layer disposed on the second semiconductor layer;
an optical layer; and
an active layer spaced apart from the optical layer in a thickness direction,
any one of the optical layer and the active layer is disposed between the first semiconductor layer and the second semiconductor layer,
another one of the optical layer and the active layer is disposed between the second semiconductor layer and the third semiconductor layer,
the optical layer includes:
a porous layer; and
a non-porous layer disposed on the porous layer, and
in a direction perpendicular to the thickness direction, a first width of the porous layer is greater than a second width of the non-porous layer.

2. The light-emitting diode of claim 1, wherein a first refractive index of the porous layer is smaller than a second refractive index of the non-porous layer.

3. The light-emitting diode of claim 1, wherein the porous layer, the non-porous layer, and any two of the first to third semiconductor layers comprise a same semiconductor material.

4. The light-emitting diode of claim 1, wherein the optical layer comprises at least one of gallium nitride (GaN), indium gallium nitride (InGaN), and aluminum gallium nitride (AlGaN).

5. The light-emitting diode of claim 1, wherein a thickness of the porous layer satisfies Equation 1 below, and a thickness of the non-porous layer satisfies Equation 2 below:
$${T}_{1} = {λ}_{0} / 4 {n}_{1} \qquad [ Equation 1 ]$$
$${T}_{2} = {λ}_{0} / 4 {n}_{2} \qquad [ Equation 2 ]$$
where, in Equation 1, n₁ is a refractive index of the porous layer, and T₁ is the thickness of the porous layer,
in Equation 2, n₂ is a refractive index of the non-porous layer, and T₂ is the thickness of the non-porous layer, and
in Equation 1 and Equation 2, λ₀ is a wavelength of light emitted from the active layer.

6. The light-emitting diode of claim 1, wherein a thickness of the non-porous layer is about 2m₀+1 times a thickness of the porous layer, where m₀ is an integer of 0 or more.

7. The light-emitting diode of claim 1, wherein
the optical layer is disposed between the second semiconductor layer and the third semiconductor layer,
the active layer is disposed between the first semiconductor layer and the second semiconductor layer,
each of the second semiconductor layer and the third semiconductor layer comprises an N-type semiconductor layer, and
the first semiconductor layer comprises a P-type semiconductor layer.

8. The light-emitting diode of claim 1, wherein
the optical layer is disposed between the first semiconductor layer and the second semiconductor layer,
the active layer is disposed between the second semiconductor layer and the third semiconductor layer,
each of the first semiconductor layer and the second semiconductor layer comprises an N-type semiconductor layer, and
the third semiconductor layer comprises a P-type semiconductor layer.

9. A display device comprising:
a complementary metal oxide semiconductor (CMOS) wafer; and
a plurality of light-emitting diodes disposed on the CMOS wafer, wherein
each of the plurality of light-emitting diodes includes:
a first electrode part;
a second electrode part disposed on the first electrode part; and
a semiconductor junction structure disposed between the first electrode part and the second electrode part,
the semiconductor junction structure includes:
a first semiconductor layer;
a second semiconductor layer disposed on the first semiconductor layer;
a third semiconductor layer disposed on the second semiconductor layer;
an optical layer; and
an active layer spaced apart from the optical layer in a thickness direction,
any one of the optical layer and the active layer is disposed between the first semiconductor layer and the second semiconductor layer,
another one of the optical layer and the active layer is disposed between the second semiconductor layer and the third semiconductor layer,
the optical layer includes:
a porous layer; and
a non-porous layer disposed on the porous layer, and
in a direction perpendicular to the thickness direction, a first width of the porous layer is greater than a second width of the non-porous layer.

10. The display device of claim 9, wherein a first refractive index of the porous layer is smaller than a second refractive index of the non-porous layer.

11. The display device of claim 9, wherein the porous layer, the non-porous layer, and any two of the first to third semiconductor layers comprise a same material.

12. The display device of claim 9, wherein the optical layer comprises at least one of gallium nitride (GaN), indium nitride (InN), and indium gallium nitride (InGaN).

13. The display device of claim 9, further comprising:
a side-surface reflection layer disposed on a side surface of the first electrode part, on a side surface of the semiconductor junction structure, on a side surface of the second electrode part, and on an upper surface of the second electrode part,
wherein the side-surface reflection layer includes at least one of gold (Au), copper (Cu), silver (Ag), titanium (Ti), and aluminum (Al).

14. The display device of claim 13, further comprising:
a side-surface insulation layer disposed on the side surface of the first electrode part, on the side surface of the semiconductor junction structure, on the side surface of the second electrode part, and on the upper surface of the second electrode part,
wherein the side-surface reflection layer is disposed on an outer side of the side-surface insulation layer.

15. The display device of claim 14, wherein on the side surface of the semiconductor junction structure, an extending direction of the side-surface insulation layer is inclined with respect to the thickness direction.

16. The display device of claim 14, wherein an opening, which exposes a partial region of the upper surface of the second electrode part, is formed through each of the side-surface reflection layer and the side-surface insulation layer.

17. The display device of claim 16, wherein
the plurality of light-emitting diodes comprise:
a first light-emitting diode including a second electrode part; and
a second light-emitting diode including a second electrode part,
the display device further comprises a common electrode configured to electrically connect the second electrode part of the first light-emitting diode and the second electrode part of the second light-emitting diode, and
the common electrode is in contact with the partial region through the opening.

18. The display device of claim 9, further comprising:
a plurality of lenses disposed on the plurality of light-emitting diodes and respectively corresponding to the plurality of light-emitting diodes.

19. A method for manufacturing a display device, the method comprising:
preparing a CMOS wafer including a first silicon substrate and a conductive layer disposed on the first silicon substrate;
preparing a semiconductor substrate including:
a preliminary semiconductor junction structure; and
a second silicon substrate disposed on the preliminary semiconductor junction structure;
coupling the CMOS wafer and the semiconductor substrate;
dry etching the preliminary semiconductor junction structure to form a semiconductor junction structure;
forming a second electrode part; and
forming a first electrode part, wherein
the forming of the second electrode part is performed simultaneously or after the forming of the semiconductor junction structure,
the semiconductor junction structure includes:
a first semiconductor layer;
a second semiconductor layer formed on the first semiconductor layer;
a third semiconductor layer formed on the second semiconductor layer;
an optical layer; and
an active layer spaced apart from the optical layer in a thickness direction,
any one of the optical layer and the active layer is formed between the first semiconductor layer and the second semiconductor layer,
another one of the optical layer and the active layer is formed between the second semiconductor layer and the third semiconductor layer, and
the optical layer includes:
a porous layer; and
a non-porous layer disposed on the porous layer, and
the porous layer and the non-porous layer are formed through electro-chemical etching after the dry etching of the preliminary semiconductor junction structure.

20. The method of claim 19, wherein in a direction perpendicular to the thickness direction, a first width of the porous layer is greater than a second width of the non-porous layer.
